(19) United States
(12) Patent Application Publication
(10) Pub. No.: US 2009/0008726 A1
(43) Pub. Date: Jan. 8, 2009

(54) METHOD OF MANUFACTURING SEMICONDUCTOR DEVICE AND SEMICONDUCTOR DEVICE

(75) Inventors: Takashi Yamauchi, Kanagawa (JP); Yoshifumi Nishi, Kanagawa (JP); Atsuhiro Kinoshita, Kanagawa (JP); Yoshinori Tsuchiya, Kanagawa (JP); Junji Koga, Kanagawa (JP); Koichi Kato, Kanagawa (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/051,947

(22) Filed: Mar. 20, 2008

(30) Foreign Application Priority Data
Jun. 20, 2007 (JP) 2007-162676

(51) Int. Cl. H01L 47/00; H01L 21/425

(52) U.S. Cl. 257/412; 438/527; 257/E47.001; 257/E21.473

(57) ABSTRACT

A method of manufacturing a semiconductor device reducing interface resistance of n-type and p-type MISFETs are provided. According to the method, a gate dielectric film and a gate electrode of the n-type MISFET are formed on a first semiconductor region, a gate dielectric film and a gate electrode of the p-type MISFET are formed on a second semiconductor region, an n-type diffusion layer is formed by ion implantation of As into the first semiconductor region, a first silicide layer is formed by first heat treatment after a first metal containing Ni is deposited on the n-type diffusion layer, the first silicide layer is made thicker by second heat treatment after a second metal containing Ni is deposited on the first silicide layer and second semiconductor region, and third heat treatment is provided after formation of a second silicide layer and ion implantation of B or Mg into the second silicide layer.

### CROSS-REFERENCE TO RELATED APPLICATION

This application is based upon and claims the benefit of priority from Japanese Patent Application No. 2007-162676, filed on Jun. 20, 2007, the entire content of which is incorporated herein by reference.

1. Field of the Invention

The present invention relates to a method of manufacturing a semiconductor device having an n-type MISFET and a p-type MISFET and such a semiconductor device.

2. Background of the Invention

A silicon large-scale integrated circuit (LSI) is one of fundamental technologies to support a highly computerized society in the future. For better functionality of an integrated circuit, a MISFET (Metal Insulator Semiconductor Field Effect Transistor), which is a component thereof, must have higher performance. Higher performance of MISFET has basically been achieved by the miniaturization based on the scaling rule. In recent years, however, due to various physical limits, it is increasingly becoming difficult not only to achieve higher performance due to a fine structure of MISFETs, but also even for MISFETs themselves to operate.

One of such physical limits is a problem of parasitic resistance in a source/drain region. FIG. 50 shows a typical MISFET of a conventional technology. As shown in FIG. 50, a silicide layer 510 is formed as a source electrode and a drain electrode. Here, a Schottky junction is formed between the silicide layer 510 and a high-concentration impurity layer 508 and an extension diffusion layer 505 formed around the silicide layer 510. Then, as shown in FIG. 50, parasitic resistance of the source/drain electrodes is classified into three kinds of resistance: resistance of the silicide layer (Rs) itself, resistance of a high-concentration impurity layer (Rd) and interface resistance of the junction (Rc).

Among these kinds of resistance, it is generally known that the interface resistance (Rc) is the greatest. In addition, the interface resistance does not decrease according to the scaling rule. Thus, for performance improvement of MISFET in the future, lowering the interface resistance is a very important challenge.

Moreover, it is also known that increasing impurity concentrations in an interface portion between the silicide layer 510 and the impurity layer 508 is important to lower the interface resistance (Rc) . In that case, it is desirable to make concentration of activated impurities high, for example, 5×10¹⁹ cm⁻³ or higher, by segregating the impurities in a narrower range from the interface, for example, 20 nm or less.

FIG. 51 shows a band diagram of a Schottky junction formed between a silicide layer and high-concentration impurity layer (Si layer). Electrons move between the silicide layer and high-concentration impurity layer by tunneling through a peak of energy corresponding to the Schottky barrier height (SBH) . The probability with which this electron tunneling occurs is generally called a tunneling probability and a junction interface with a higher tunneling probability will have lower interface resistance.

Further, it is known that the tunneling probability decreases exponentially with a product of the Schottky barrier height and a tunnel distance. Thus, decreasing the Schottky barrier height and the tunnel distance effectually leads to lowering in the interface resistance.

By increasing impurity concentrations at an interface between the silicide layer and high-concentration impurity layer and causing impurity to segregate in narrow range, as shown in FIG. 52, an effect of increasing a curvature of the band of the Si layer shows up, decreasing the tunnel distance. Further, as is evident from the band diagram in FIG. 52 calculated by factoring in a image charge effect, the Schottky barrier height itself decreases. Therefore, the product of the Schottky barrier height and tunnel distance decreases, realizing the lowering of the interface resistance (Rc).

Regarding resistance of the silicide layer (Rs) itself, on the other hand, NiSi (nickel silicide) films having lower resistance than conventional TiSi₂ (titanium silicide) and CoSi₂ (cobalt silicide) are increasingly used in recent years. NiSi films are regarded as promising because, in addition to lower resistance, NiSi films can be formed at a lower temperature, an Si consumption for forming a silicide is smaller and thus, a thinner silicide layer can be formed, and their work function is near a mid-gap of the Si (silicon) band and thus, NiSi films are suitable for simultaneous application as silicide material of both n-type and p-type MISFETs. FIG. 53 shows a typical process flow when an NiSi film is applied to a silicide layer.

NiSi is, as described above, regarded as a promising silicide material. Thus, also in order to lower interface resistance (Rc) of the junction, particularly lowering resistance at an interface between the NiSi layer and Si layer is becoming one of the most important challenges.

A technology, a so-called impurity segregation process in which an impurity layer formed by ion implantation before a silicide has been disclosed as a technique to realize lower resistance of the interface resistance (Rc) between the NiSi layer and Si layer (For example, A. Kinoshita et al. , “Successful CMOS Operation of Dopant—Segregation Schottky Barrier Transistors (DS-SBTs) , Extended Abstracts of SSDM, pp. 172-173 (2004)). In this process, segregation of impurities occurs at an interface between the NiSi layer and Si layer when the silicide is formed to form a high-concentration impurity segregation layer at the interface

FIG. 54 shows a result of observation by backside SIMS (Secondary Ion Mass Spectroscopy) of an interface of the NiSi layer/Si layer created by the impurity segregation process. FIG. 54A shows a case of As (arsenic) as an impurity and FIG. 54B shows a case of B (boron) as an impurity.

When As (arsenic) , which is a typical impurity of n-type Si is used, as shown in FIG. 54A, the impurity is distributed on both sides of the interface. In contrast, when B (boron) , which is a typical impurity of p-type Si is used, as shown in FIG. 54B, B is incorporated into the NiSi film during silicidation and thus, most of B is distributed inside the NiSi film, making impurity concentrations on the Si film side extremely low.

Though the impurity segregation process is useful to achieve higher performance of n-type MISFET, as described above, the process is not necessarily useful for p-type MISFET. Thus, the process is not yet sufficient to achieve higher performance of a semiconductor device of a CMIS (Complementary Metal Insulator Semiconductor) structure having both the n-type MISFET and p-type MISFET.

For improvement of characteristics of a semiconductor device of the CMIS structure, as described above, a technology to realize lower resistance of the interface resistance (Rc) of the p-type MISFET simultaneously with lower resistance of the interface resistance (Rc) of the n-type MISFET has been demanded.

The inventors have reported that a so-called “impurity post-implantation process” in which ion implantation is performed after an NiSi layer is formed is suitable to realize lower resistance of the interface resistance (Rc) of p-type MISFET (T. Yamauchi et al., “1 nm Nisi/Si Junction Design based on First-Principles Calculation for Ultimately Low Contact Resistance”, IEDM Tech. Dig., p. 385 (2006)). This impurity post-implantation process is extremely effective in making the interface resistance (Rc) of p-type MISFET lower. Naturally, in a semiconductor device of the CMIS structure, the manufacturing method and device structure must be optimized to make the impurity post-implantation process compatible with an effort to make the interface resistance (Rc) of n-type MISFET lower.

### BRIEF SUMMARY OF THE INVENTION

A manufacturing method of a semiconductor device in accordance with a first aspect of the present invention is a manufacturing method of a semiconductor device having an n-type MISFET and a p-type MISFET on a semiconductor substrate that comprises forming a gate dielectric film of the n-type MISFET on a first semiconductor region of the semiconductor substrate; forming a gate dielectric film of the p-type MISFET on a second semiconductor region of the semiconductor substrate; forming a gate electrode of the n-type MISFET on the gate dielectric film of the n-type MISFET; forming a gate electrode of the p-type MISFET on the gate dielectric film of the p-type MISFET; forming an n-type diffusion layer by ion implantation of As into the first semiconductor region; depositing a first metal containing Ni onto the n-type diffusion layer; forming a first silicide layer through silicidation of the n-type diffusion layer by first heat treatment; making the first silicide layer thicker through silicidation of the first semiconductor region; depositing a second metal containing Ni onto the first sicilide layer and the second semiconductor region; making the first silicide layer thicker through silicidation of the first semiconductor region and forming a second silicide layer through silicidation of the second semiconductor region by second heat treatment; and providing third heat treatment after ion implantation of B or Mg into the second silicide layer.

A method of a semiconductor device in accordance with a second aspect of the present invention is a manufacturing method of a semiconductor device having an n-type MISFET and a p-type MISFET on a semiconductor substrate that comprises forming a gate dielectric film of the n-type MISFET on a first semiconductor region of the semiconductor substrate; forming a gate dielectric film of the p-type MISFET on a second semiconductor region of the semiconductor substrate; forming a gate electrode of the n-type MISFET on the gate dielectric film of the n-type MISFET; forming a gate electrode of the p-type MISFET on the gate dielectric film of the p-type MISFET; forming an n-type diffusion layer by ion implantation of As into the first semiconductor region; depositing a first metal containing Ni onto the first semiconductor region; forming a first silicide layer through silicidation of the first semiconductor region by ion implantation of As into the first metal; depositing a second metal containing Ni onto the first sicilide layer and the second semiconductor region; making the first silicide layer thicker through silicidation of the first semiconductor region and forming a second silicide layer through silicidation of the second semiconductor region by first heat treatment; and providing second heat treatment after ion implantation of B or Mg into the second silicide layer.

A semiconductor device in accordance with an aspect of the present invention is a semiconductor device having an n-type MISFET and a p-type MISFET on a semiconductor substrate in which the n-type MISFET comprises a first channel region in the semiconductor substrate; a first gate dielectric film formed on the first channel region; a first gate electrode formed on the first gate dielectric film; a source electrode and a drain electrode formed of a first silicide layer containing Ni on both sides of the first channel region; and an As segregation layer formed between the first channel region and the first silicide layer, the p-type MISFET comprises a second channel region in the semiconductor substrate; a second gate dielectric film formed on the second channel region; a second gate electrode formed on the second gate dielectric film; a source electrode and a drain electrode formed of a second silicide layer containing Ni on both sides of the second channel region; and a segregation layer containing B or Mg formed between the second channel region and the second silicide layer, and the first silicide layer is thicker than the second silicide layer.

### BRIEF DESCRIPTION OF THE DRAWINGS

FIG. 1 is a diagram showing a semiconductor device in a first embodiment.

FIG. 2 is a diagram showing a process flow of an impurity post-implantation process.

FIG. 3 is a diagram showing a result of analysis by SIMS of an impurity distribution at a NiSi layer/Si layer interface created by the impurity post-implantation process.

FIG. 4 is a diagram showing a result of measurement of voltage-current characteristics at the NiSi layer/Si layer interface created by the impurity post-implantation process of B atoms.

FIG. 5 is a diagram showing an SIMS analysis result when the impurity post-implantation process is applied to As atoms.

FIG. 6 is a diagram showing a result of calculation of changes of energy of the interface structure corresponding to a substitutional position of the impurity atoms.

FIG. 7 is an illustration of a process in which B atoms are segregated in the impurity post-implantation process of B atoms.

FIG. 8 is a process flow applying an impurity segregation process to As and the impurity post-implantation process to B.

FIG. 9 to FIG. 17 are sectional views of showing a manufacturing process of the semiconductor device in the first embodiment.

FIG. 18 is a diagram showing a result of calculation of changes of energy of the interface structure corresponding to the substitutional position of the Mg atoms.

FIG. 19 is a diagram showing a result of calculation of a Schottky barrier height when an impurity segregation layer is formed by Mg atoms.

FIG. 20 and FIG. 21 are sectional views showing the manufacturing process of a semiconductor device in a fourth embodiment.

FIG. 22 is a perspective view of a semiconductor device in a fifth embodiment.

FIG. 23 to FIG. 49 are sectional views showing the manufacturing process of a semiconductor device in the fifth embodiment.

FIG. 50 is a diagram showing a typical MISFET of a conventional technology.

FIG. 51 is a band diagram of a Schottly junction formed between a silicide film and a high-concentration impurity region (Si layer).

FIG. 52 is a diagram showing a difference of band curves due to a difference in impurity concentrations of the Si layer.

FIG. 53 is a diagram showing a conventional NiSi layer formation process.

FIG. 54 is a diagram showing a result of observation by second-surface SIMS of an interface between the NiSi layer and the high-concentration impurity Si layer.

### DETAILED DESCRIPTION OF THE EMBODIMENTS

As described above, the inventors of the present invention have reported that the so-called “impurity post-implantation process” in which ion implantation of B is performed after an NiSi layer is formed is suitable to realize lower resistance of the interface resistance (Rc) of p-type MISFET. The present invention optimizes the impurity post-implantation process and the impurity segregation process considered to be effective in making the interface resistance (Rc) of n-type MISFET lower after combining both processes to achieve higher performance of a semiconductor device having the CMIS structure.

Thus, first the impurity post-implantation process that forms the basis of the present invention will be briefly described. Then, comparison between the impurity post-implantation process and the impurity segregation process is briefly described, including a theoretical analysis result.

FIG. 2 shows a process flow of the impurity post-implantation process. In this process, an NiSi layer is once formed and then, ion implantation of impurities such as B into the NiSi layer is performed. Subsequently, impurities implanted in the NiSi layer are caused to diffuse toward an NiSi layer/Si layer interface by annealing.

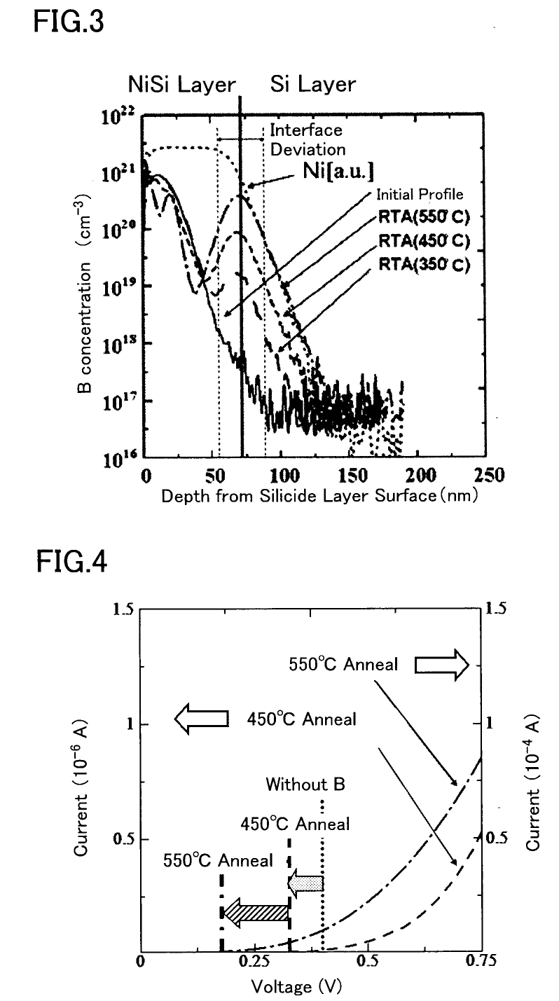

FIG. 3 shows a result of analysis by SIMS of an impurity distribution at the NiSi layer/Si layer interface created by the impurity post-implantation process. The horizontal axis shows the depth from the silicide layer surface and the vertical axis shows B concentrations. The distribution of Ni is also shown for identification of the interface position.

The NiSi layer/Si layer interface position by the SIMS analysis is herein defined as follows: an area where the Ni concentration falls by an order of magnitude from that of the NiSi layer of the bulk is defined as interface distribution and the half-value position of the depth range of the interface distribution is defined as an NiSi layer/Si layer interface position. FIG. 3 shows also the interface distribution and interface position based on these definitions.

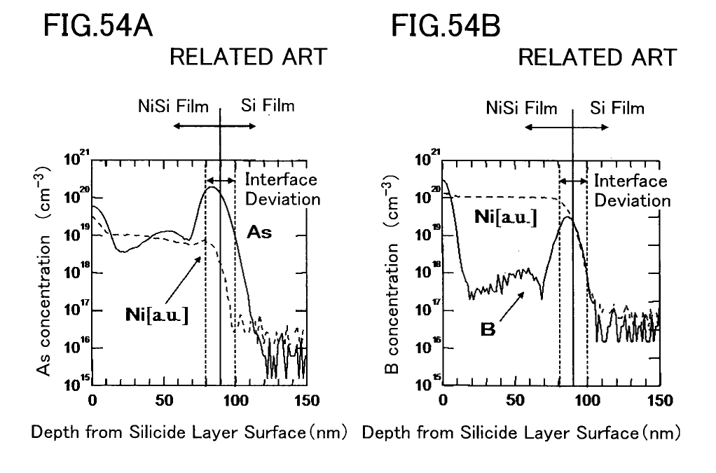

As is evident from FIG. 3, with a rising annealing temperature after ion implantation, B atoms move from the surface side in a direction of the interface before being piled up near the interface. Then, a peak B concentration is about the order of a solubility limit (5.0×10²⁰ atoms/cm³) of B in silicon. This peak concentration is about an order of magnitude greater than that in the impurity segregation process shown in FIG. 54B. It is also clear that the B concentration in the Si layer side is higher than that in the impurity segregation process.

Next, FIG. 4 shows a result of measurement of voltage-current characteristics at the NiSi layer/Si layer interface created by the impurity post-implantation process of B atoms. Samples of the annealing temperatures of 450° C. and 550° C. after implantation of B ions were prepared. Measurements were made at 50K in a temperature range in which a tunnel current is dominant. By making measurements after applying a positive voltage to the Si layer side at this temperature and monitoring the voltage (VF) at which the current rises, the Schottky barrier height (SBH) was estimated. The SBH between the NiSi layer and Si layer at the annealing temperature of 550° C. is lower by about 0.2 eV compared with that of an intrinsic semiconductor having no B in the Si layer. It is known that, though not shown, the SBH falls by about 0.15 eV when the impurity segregation process is applied. Thus, superiority of the impurity post-implantation process of B over the impurity segregation process is also demonstrated by electrical characteristics. According to the impurity post-implantation process, as described above, impurity concentrations near the NiSi layer/Si layer interface can be made higher if B is used as an impurity and, as a result, the SBH can be lowered. Therefore, the process can be considered to be extremely effective in realizing lower resistance of the interface resistance (Rc) of p-type MISFET.

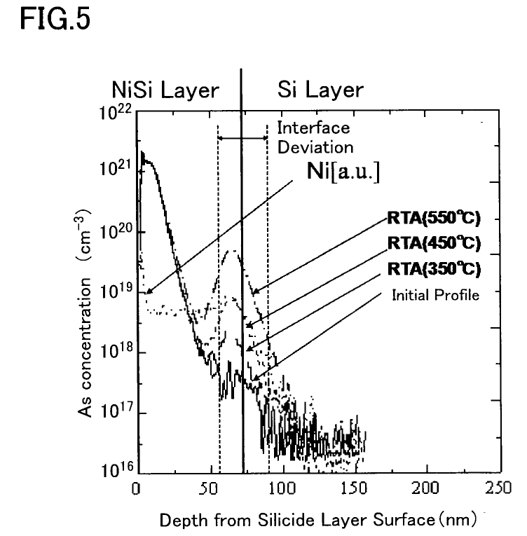

FIG. 5 shows an SIMS analysis result obtained when the inventors applied the impurity post-implantation process to As atoms for comparison with B atoms. As is evident from comparison of this result with that in FIG. 54(a), the peak concentration of As atoms at the NiSi layer/Si layer interface is not only lower than that created by the impurity segregation process, but also the whole distribution is moved toward the NiSi layer side. Therefore, the impurity post-implantation process is effective for p-type MISFETs, but cannot be considered always to be effective for n-type MISFETs.

Next, a result of theoretical analysis by the inventors of a difference between impurity distribution at the NiSi layer/Si layer interface when the impurity post-implantation process is applied and that when the impurity segregation process is applied is briefly described. The technique of SP-GGA (Spin-Polarized Generalized Gradient Approximation) that takes spin polarization into consideration when an approximation of local density functional approximation is exceeded was adopted as the calculation method.

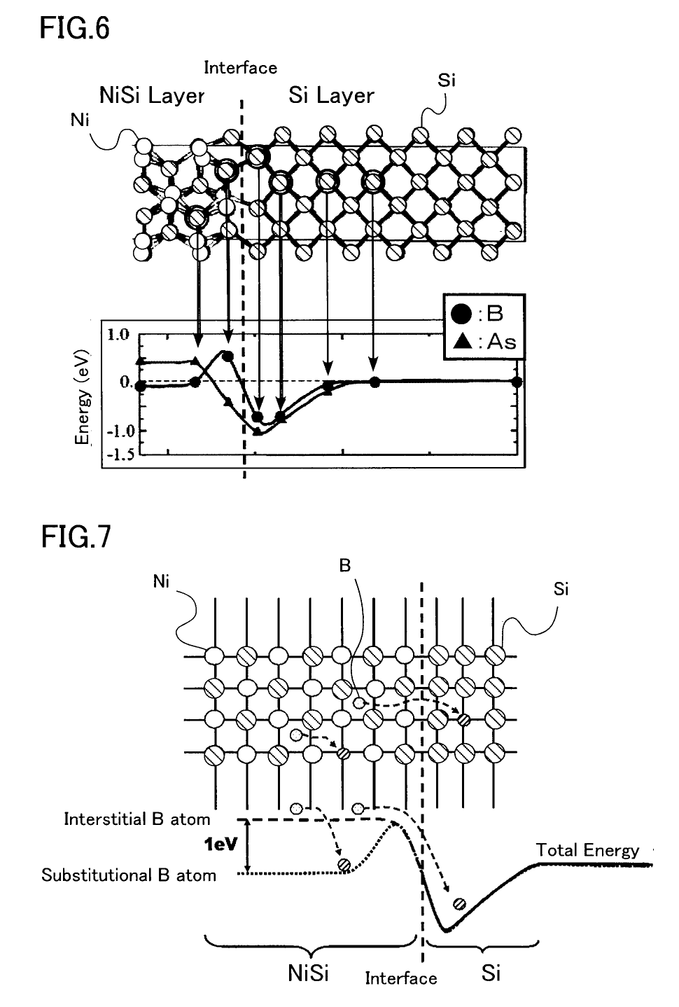

First, when impurity atoms are substituted for Si atoms in the NiSi layer/Si layer interface structure, how energy of the interface structure changes in accordance with the substitutional position of impurity atoms was calculated. A calculation result is shown in FIG. 6. A graph on the lower side is a result of plotting total energy of a corresponding crystal structure when each of Si atoms surrounded by a circle is replaced by one B atom or As atom in a crystal structure diagram on the upper side of FIG. 6. A crystal structure with lower energy is considered to be more stable. The reference (0 value) of energy is selected to be a case in which impurity atoms substitute for Si atoms in an Si bulk layer, that is, energy plotted at the right edge of the graph.

If, in the graph, a black circle is a case in which an Si atom is replaced by a B atom, a black triangle is a case in which an Si atom is replaced by an As atom. In both cases of impurities, the graph shows that energy is lowest when Si atoms near the interface are replaced and an energetically most stable site exists near the interface. Therefore, causing B atoms or As atoms to segregate at the NiSi layer/Si layer interface can theoretically be considered to be possible.

A process of segregating B atoms at the NiSi layer/Si layer interface in the impurity post-implantation process for B atoms will be described with reference to FIG. 7. First, B atoms after being implanted in the NiSi layer by ion implantation hold interstitial positions of NiSi. If, as shown in FIG. 7, a B atom is present at an interstitial position, energy of the system is higher by about 1 eV than when the B atom is at a substitutional position.

Thus, a portion of B atoms will hold substitutional positions of the NiSi layer of a bulk. However, many of B atoms introduced into many interstitial positions will hold substitutional positions near the interface that are more stable than those of the NiSi layer of the bulk by diffusion caused by annealing. In this manner, segregation of B atoms occurs at the NiSi layer/Si layer interface.

Indeed, segregation of B atoms at an interface is not often observed when the impurity segregation process is applied. This can be explained as follows: B atoms introduced into substitutional positions in Si before silicidation temporarily hold interstitial positions in a process of silicidation. Since, at this time, it is predominantly stable for B atoms to hold interstitial positions of the NiSi layer rather than being present at interstitial positions of Si, B atoms will be absorbed by the NiSi layer. Then, B atoms will subsequently be settled at substitutional positions in the NiSi layer in the stable bulk earlier than returning by diffusing into the Si layer. Also, as is evident from FIG. 6, B atoms are more stable at substitutional positions in the NiSi layer of the bulk than in the Si layer of the bulk. This fact also suppresses movement of B atoms to the interface.

On the other hand, As atoms are, like B atoms, energetically more stable at an interface. However, in contrast to B atoms, diffusion of As atoms caused by annealing is slow due, for example, to the fact that the atomic radius of As atoms is larger than that of B atoms. Therefore, implanted As atoms are considered to be more likely to hold substitutional positions in the NiSi layer rather than being segregated near the interface in the impurity post-implantation process.

In contrast to B atoms, as is evident from FIG. 6, it is energetically more stable for As atoms, on the other hand, to enter the bulk of the Si layer rather than being at substitutional positions of the bulk NiSi layer. Thus, according to the impurity segregation process, As atoms are considered to be able to hold substitutional positions near the NiSi layer/Si layer interface before being segregated near the interface.

The inventors have shown experimentally and theoretically, as described above, that in order to realize lower resistance at the NiSi layer/Si layer interface, the impurity post-implantation process is effective for the p-type MISFET in which B atoms are used as impurities and the impurity segregation process is effective for the n-type MISFET in which As atoms are used as impurities.

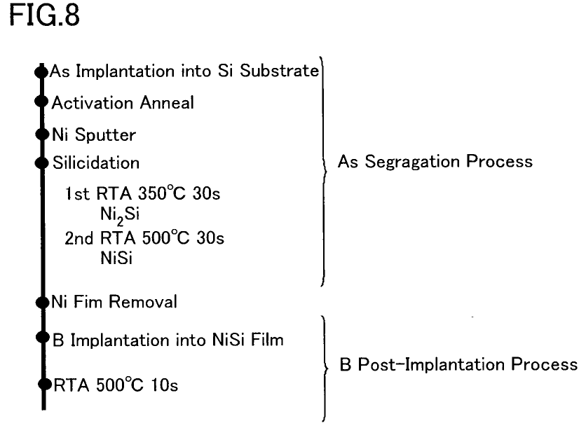

Thus, in the manufacture of a semiconductor device of the CMIS structure, as shown in FIG. 8, it is most desirable to combine two processes: the impurity segregation process for As and the impurity post-implantation process for B.

Indeed, the inventors found that in order to optimize both interface resistance of n-type MISFET and that of p-type MISFET, even the process shown in FIG. 8 is not sufficient. That is, a semiconductor device formed by the process shown in FIG. 8 has silicide layers of the same thickness both for n-type MISFET and p-type MISFET. However, it is desirable actually to make silicide layers of the source/drain of n-type MISFET thicker than those of p-type MISFET.

First, in the impurity segregation process of As, As atoms implanted earlier are collected by a so-called snow plow effect during silicide formation to cause As to segregate at the interface. Therefore, the silicide layer is preferably thicker in order to cause more As to segregate at the interface.

In the impurity post-implantation process of B, on the other hand, if the silicide layer becomes thicker, it is necessary to increase accelerating energy of ion implantation of B in order to increase concentrations of B implanted in the vicinity of interface between the silicide layer and Si layer. Then, as accelerating energy increases, distribution in a depth direction of B also widens. Thus, B atoms introduced into the Si layer by ion implantation increases, instead of the NiSi layer. Moreover, a short channel effect of p-type MISFET could be degraded by a diffusion layer formed by the B atoms. Therefore, for the impurity post-implantation process of B, the silicide layer is preferably thinner.

Thus, when combining the impurity segregation process and the impurity post-implantation process, there is a problem that optimal thickness of a silicide layer for n-type MISFET and that for p-type MISFET are different.

In a manufacturing method of a semiconductor device in embodiments of the present invention described below, in order to form silicide layers having different thicknesses for the n-type MISFET and the p-type MISFET, first a silicide layer of a predetermined thickness is formed for the n-type MISFET. Then, the silicide layer of the n-type MISFET is made thicker and a silicide layer for the p-type MISFET is formed simultaneously.

If an attempt is made to form silicide layers having different thicknesses for the n-type MISFET and the p-type MISFET using a conventional technology, each silicide layer has to be formed independently. That is, for example, a silicide layer for then-type MISFET is first formed. Then, a silicide layer for the p-type MISFET is formed while the n-type MISFET is masked.

Thus, if silicide layers are formed completely independently, the heat treatment time needed for a silicide layer for the n-type MISFET formed earlier will become longer by that needed for formation of a silicide layer for the p-type MISFET. Thus, a possibility of anomalous diffusion of Ni increases. In addition, a process of masking the n-type MISFET is added, leading to more complicated processes.

According to a manufacturing method in embodiments of the present invention, a silicide layer for the n-type MISFET is made thicker and a silicide layer for the p-type MISFET is formed simultaneously and therefore, the heat treatment time needed for the silicide layer of the n-type MISFET can be reduced. Also, the process of masking the n-type MISFET can be eliminated, leading to simpler processes.

### FIRST EMBODIMENT

A manufacturing method of a semiconductor device in the first embodiment is a manufacturing method of a semiconductor device having an n-type MISFET and a p-type MISFET on a semiconductor substrate. Then, a gate dielectric film of the n-type MISFET is formed in a first semiconductor region of the semiconductor substrate and a gate dielectric film of the p-type MISFET is formed in a second semiconductor region of the semiconductor substrate. Then, a gate electrode of the n-type MISFET is formed on the gate dielectric film of the n-type MISFET and a gate electrode of the p-type MISFET is formed on the gate dielectric film of the p-type MISFET. Then, an n-type diffusion layer is formed by ion implantation of As into the first semiconductor region and a first silicide layer is formed through silicidation of the first semiconductor region by first heat treatment after a first metal containing Ni being deposited onto the first semiconductor region. Then, the first silicide layer is made thicker through silicidation of the first semiconductor region and a second silicide layer is formed through silicidation of the second semiconductor region caused by second heat treatment after a second metal containing Ni being deposited onto the first sicilide layer and the second semiconductor region. Further, third heat treatment is provided after ion implantation of B or Mg into the second silicide layer.

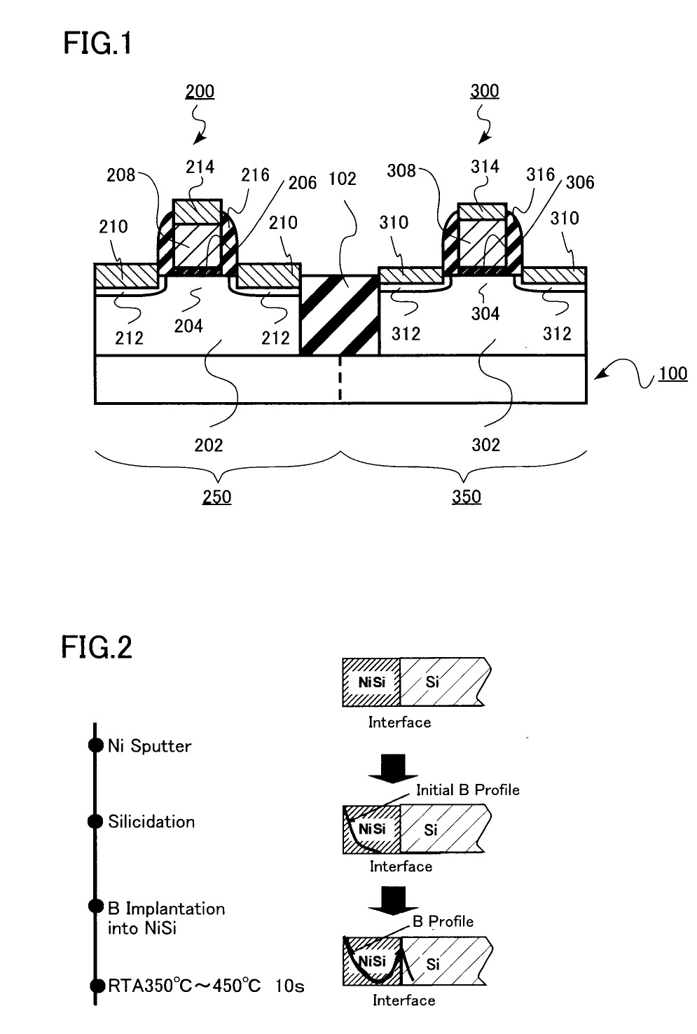

FIG. 1 is a sectional view of a semiconductor device in the present embodiment formed by a manufacturing method of a semiconductor device in the present embodiment. This semiconductor device has, for example, an n-type MISFET 200 and a p-type MISFET 300 on a semiconductor substrate 100 of silicon. The n-type MISFET 200 is formed on a p well 202 formed on the semiconductor substrate 100. The p-type MISFET 300 is formed on an n well 302 formed on the semiconductor substrate 100. Then, an device isolation region 102 is formed at a boundary between an area where the n-type MISFET 200 is formed an area where the p-type MISFET 300 is formed. The device isolation region 102 is, for example, an STI (Shallow Trench Isolation) in which a silicon oxide is buried.

Then, the n-type MISFET 200 has a first channel region 204 in the semiconductor substrate 100, a first gate dielectric film 206 formed on the first channel region 204, and a first gate electrode 208 formed on the first gate dielectric film 206. Further, the n-type MISFET 200 has on both sides of the first channel region 204 a source electrode and a drain electrode formed from a first silicide layer 210 made of, for example, NiSi and an As segregation layer 212 formed between the first channel region 204 and the first silicide layer 210. The first silicide layer 210 has a concentration of, for example, 8×10¹⁹ to 5×10²⁰ atoms/cm³.

Also, a first gate silicide layer 214 made of, for example, NiSi is formed on the gate electrode 208 of the n-type MISFET 200. Moreover, sidewall dielectric films 216 made of, for example, a silicon nitride film are formed on both sides of the gate electrode 208.

Then, the p-type MISFET 300 has a second channel region 304 in the semiconductor substrate 100, a second gate dielectric film 306 formed on the second channel region 304, and a second gate electrode 308 formed on the second gate dielectric film 306. Further, the p-type MISFET 300 has on both sides of the second channel region 304 a source electrode and a drain electrode formed from a second silicide layer 310 made of, for example, NiSi and a B segregation layer 312 formed between the second channel region 304 and second silicide layer 310. The second silicide layer has a concentration of, for example, 8×10¹⁹ to 5×10^{°} atoms/cm³.

Also, a second gate silicide layer 314 made of, for example, NiSi is formed on the gate electrode 308 of the p-type MISFET 300. Moreover, sidewall dielectric films 316 made of, for example, a silicon nitride film are formed on both sides of the gate electrode 308. In this semiconductor device, the first silicide layer 210 of the n-type MISFET is thicker than the second silicide layer 310 of the p-type MISFET.

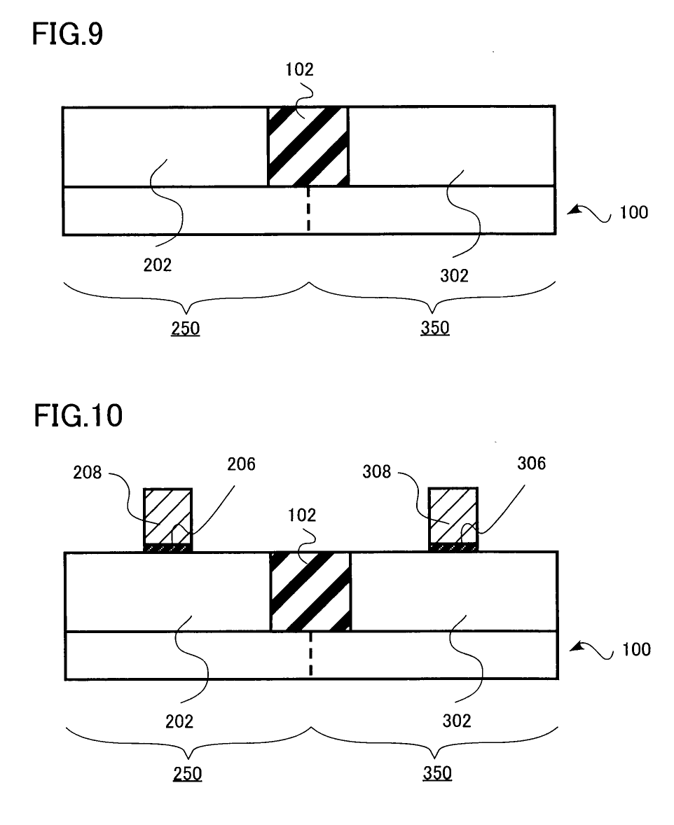

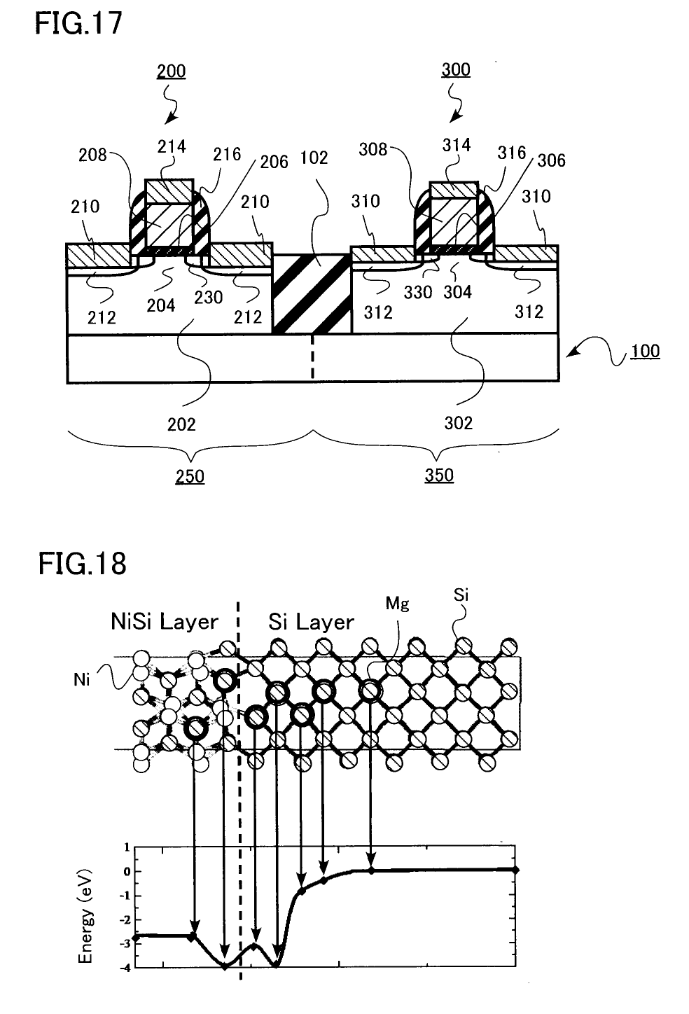

Next, the manufacturing method of a semiconductor device in the present embodiment will be described with reference to FIG. 9 or FIG. 17. First, as shown in FIG. 9, the device isolation region (STI (Shallow Trench Isolation)) 102 made of a silicon oxide is formed on the silicon substrate 100 of p type of a surface direction (100) surface where, for example, 10¹⁵ atoms/cm³ or so of B (boron) is doped. The element isolation region 102 is formed at a boundary between a first semiconductor region 250 where an n-type MISFET is formed later and a second semiconductor region 350 where a p-type MISFET is formed. Then, the p well 202 and the n well 302 are formed by ion implantation of impurities.

Next, as shown in FIG. 10, 1 nm EOT or so of the first gate dielectric film 206 formed of, for example, a silicon oxide is formed on the first semiconductor region 250. Similarly, 1 nm EOT or so of the second gate dielectric film 306 formed of, for example, a silicon oxide is formed on the second semiconductor region 350. These first gate dielectric film 206 and second gate dielectric film 306 may be formed simultaneously.

Then, a polysilicon film of the order of 100 to 150 nm to be the first gate electrode 208 is deposited on the first gate dielectric film 206 by the low-pressure chemical vapor deposition (hereinafter referred to as LP-CVD). Then, a pattern is formed by process technology such as lithography technology and reactive ion etching (herein after also referred to as RIE) so that the gate length of the first gate dielectric film 206 and the first gate electrode 208 becomes about 30 nm.

Then, similarly a polysilicon film of the order of 100 to 150 nm to be the second gate electrode 308 is deposited on the second gate dielectric film 306 by the low-pressure chemical vapor deposition (hereinafter referred to as LP-CVD). Then, a pattern is formed using process technology such as lithography technology and reactive ion etching (hereinafter also referred to as RIE) so that the gate length of the second gate dielectric film 306 and the second gate electrode 308 becomes about 30 nm.

Incidentally, deposition of the polysilicon film and pattern formation of the first gate dielectric film 206 and first gate electrode 208 and that of the second gate dielectric film 306 and second gate electrode 308 may be performed simultaneously in the n-type MISFET and p-type MISFET. If necessary, post oxidization of 1 to 2 nm is performed here.

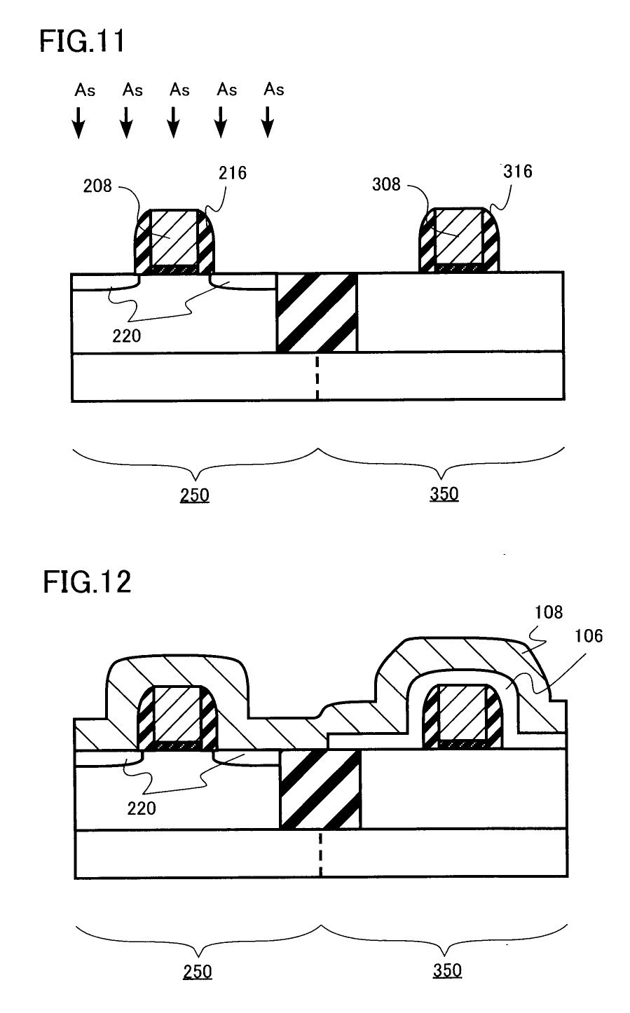

Next, as shown in FIG. 11, a silicon nitride film of the order of, for example, 8 nm is deposited by the LP-CVD method and then, the silicon nitride film is etched back by the RIE method to leave only portions thereof on both sides of the first gate electrode 208 and second gate electrode 308. The sidewall dielectric films 216 and sidewall dielectric films 316 are thereby formed.

Next, the second semiconductor region 350 is masked with a resist film by lithography and the first gate electrode 208 and sidewall dielectric films 216 are used as a mask to introduce As (arsenic) into the first semiconductor region 250 by ion implantation. An n-type diffusion layer 220 of the order of, for example, 1×10²¹ atoms/cm³ is thereby formed.

Next, as shown in FIG. 12, a protective film 106 made of, for example, a silicon oxide is formed only on the second semiconductor region 350 by deposition using the LP-CVD method and patterning using lithography and RIE. Then, a Ni film 108 of the order of, for example, 10 nm in thickness is formed by, for example, the sputtering method as a first metal on the first semiconductor region 250. That is, the Ni film 108 is deposited in such a way that the Ni film 108 is in contact with the source and drain regions of the n-type MISFET.

Then, as shown in FIG. 13, annealing is performed at 350° C. for about 30 seconds by, for example, RTA as first heat treatment to form the first silicide layer 210 having the thickness of about 20 nm and made of NiSi through silicidation of the first semiconductor region 250. At this time, the first gate silicide layer 214 is also formed on the gate electrode 208. Subsequently, the unreacted excessive Ni film 108 is separated by a chemical solution. The first silicide layer 210 will be the source/drain electrodes of then-type MISFET. With the n-type diffusion layer 220 being silicided when the first silicide layer 210 is formed, the As segregation layer 212 is formed as an interface, that is, an NiSi layer/Si layer interface of the first silicide layer 210.

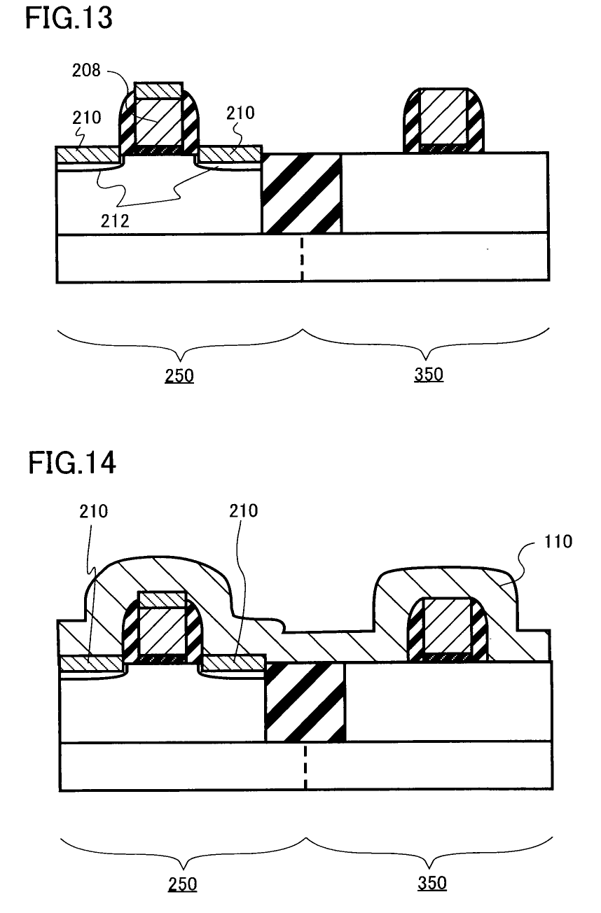

Next, as shown in FIG. 14, an Ni film 110 of the order of, for example, 8 nm in thickness is deposited by, for example, the sputtering method as a second metal on the first semiconductor region 250 and the second semiconductor region 350. Subsequently, as shown in FIG. 15, annealing is performed at 500° C. for about 30 seconds by, for example, RTA as second heat treatment. Then, the first semiconductor region 250 formed earlier below the first silicide layer 210 is silicided to make the first silicide layer 210 thicker. The first silicide layer 210 will have the thickness of about 36 nm.

Incidentally, it is desirable to silicide the first semiconductor region 250 by the first heat treatment and second heat treatment and also by third heat treatment to be described later up to a portion of the first semiconductor region 250 deeper than the n-type diffusion layer 220 before silicidation. That is, it is desirable that the depth of the first silicide layer 210 formed finally be deeper than the depth of the n-type diffusion layer immediately before the Ni film 108, which is the first metal, being deposited. Here, reference point (plane) of depth may be interface between the gate dielectric film and the Si substrate. Accordingly, more As in the n-type diffusion layer 220 can be caused to segregate at the interface of the first silicide layer 210 with a steeper concentration profile, realizing a further reduction in the Schottky barrier.

At the same time, the second semiconductor region 350 is silicided to form the second silicide layer 310 made of NiSi and of the order of 16 nm in thickness. The second silicide layer 310 will be the source/drain electrodes of the p-type MISFET. At this time, the second gate silicide layer 314 is also formed on the gate electrode 308. Subsequently, the unreacted excessive Ni film 110 is separated by a chemical solution.

Here, it is desirable that the temperature of the first heat treatment be lower than that of the second heat treatment. The sicilide of nickel has many phases. Die-nickel silicide (Ni₂Si) is formed at the lowest annealing temperature and with the rising annealing temperature, nickel mono-silicide (NiSi) and nickel die-silicide (NiSi₂) are formed in this order.

As has been described above, nickel mono-silicide (NiSi) is preferably applied to LSI. Thus, an adequately high annealing temperature to form nickel mono-silicide (NiSi) is required for the second heat treatment. However, nickel mono-silicide (NiSi) need not be formed as the first silicide layer in the first heat treatment. That is, it is sufficient to have an annealing temperature for forming die-nickel silicide (Ni₂Si) that can provide a selection for separating excessive Ni later. Then, it becomes possible to form nickel mono-silicide (NiSi) as the first silicide layer by the subsequent second heat treatment and third heat treatment. Here, by setting the temperature of the first heat treatment lower than that of the second heat treatment, it becomes possible to inhibit an increase in junction leakage caused by anomalous diffusion of Ni in the first silicide layer through an excessive thermal process.

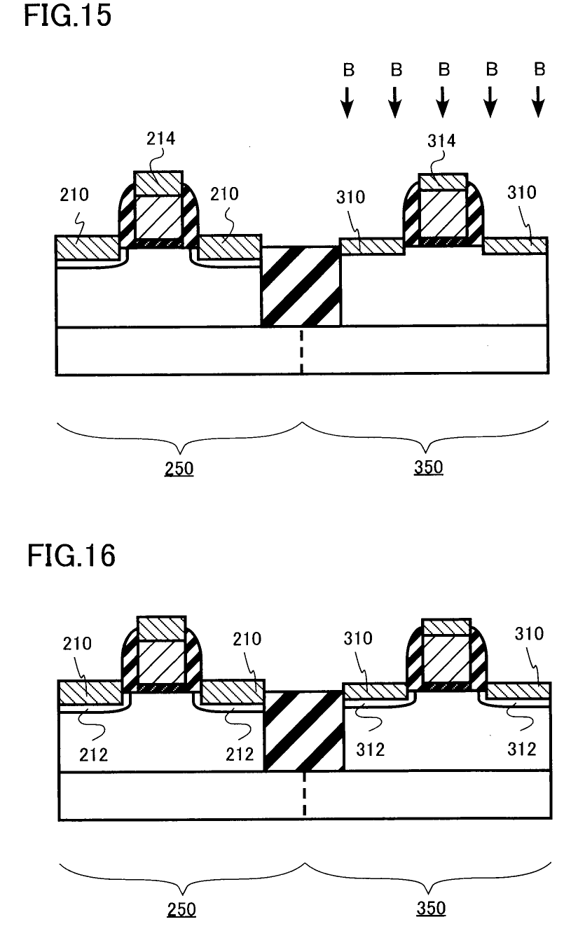

Next, as shown in FIG. 15, the first semiconductor region 250 is covered with a resist film (not shown) and then, ion implantation of B atoms onto the second semiconductor region 350 is performed. The B atoms will be introduced into the second silicide layer 310. Then, as shown in FIG. 16, annealing is performed at 500° C. for about 10 seconds by, for example, RTA as the third heat treatment. The B segregation layer 312 is formed by the annealing with B atoms being segregated at the interface of the second silicide layer 310, that is, at the NiSi layer/Si layer interface.

It is desirable that the temperature of the third heat treatment be 350° C. or more and 500° C. or less. If the temperature falls below this range, the concentration of the segregation layer may not be sufficiently high. If this range is exceeded, junction leakage caused by anomalous diffusion of Ni in the first and second silicide layers into the Si layer could increase.

Incidentally, it is desirable that ion implantation conditions be set so that a peak concentration position of B atoms immediately after ion implantation is located in the second silicide layer 310. This is because it becomes thereby possible to cause B atoms to segregate effectively and to further increase impurity concentrations in the B segregation layer 312.

In the manner described above, the first silicide layer 210 to be the source/drain electrodes of the n-type MISFET and the second silicide layer 310 to be the source/drain electrodes of the p-type MISFET are formed. Then, the first silicide layer 210 is formed thicker than the second silicide layer 310.

In addition, it is desirable that the thickness of the first silicide layer after the third heat treatment is at least twice that of the second silicide layer after the third heat treatment. By making the first silicide layer at least twice as thick as the second silicide layer, the interface resistance of the n-type MISFET and that of the p-type MISFET can be made equal. A reason for this will theoretically be described below.

If a difference between the maximum value and minimum value of an As atom of total energy in an interface structure shown in FIG. 6 is defined as ΔE_{As},

ΔE_{As}≈1.4 eV

and As atoms are considered to move toward the Si layer in accordance with this energy difference in the impurity segregation process.

The energy barrier of a B atom to be overcome to move from the NiSi layer to the Si layer, on the other hand, is 0.7 eV from FIG. 6. However, the diffusion barrier of B atoms in the NiSi layer is 1.35 eV, which is greater than the energy barrier. Therefore, the height of energy barrier actually constraining movement of B atoms from the NiSi layer to the Si layer is given by:

ΔAE_{B}≈1.35 eV

Thus, for example, the probability of B atom entering the Si layer at the annealing temperature of 500° C. (=773 K) is about twice that of As atoms from the formula below.

exp (ΔE_{As}−ΔE_{B}/kT)≈2.0

Thus, by making the NiSi layer of the source/drain electrodes of the n-type MISFET twice as thick as that of the p-type MISFET, the concentration of impurities segregated in the Si layer side can be made equal when the amount of impurities and process temperature are equal. Thus, the height of Schottky barrier will be equal so that the interface resistance can be made equal.

Further, mobility of electrons, which are carriers of n-type MISFET, is twice or more as great as that of holes which are carriers of p-type MISFET. Thus, in order to improve transistor performance in the n-type MISFET, it is more necessary to further reduce the interface resistance of the source/drain electrodes and resistance itself of bulk of the source/drain electrodes than in the p-type MISFET. Therefore, the n-type MISFET preferably has the NiSi layer twice or more as thick as that of the p-type MISFET so that the interface resistance in the n-type MISFET is equal to or more than that in the p-type MISFET. Then, also from the viewpoint of making resistance of the bulk NiSi layer ½ or less to adjust to channel resistance, which is inversely proportional to channel mobility, the NiSi layer of the n-type MISFET is preferably twice or more as thick as that of the p-type MISFET.

According to the manufacturing method of a semiconductor device in the present embodiment, the thickness of silicide layer to be the source/drain electrodes of each of the n-type MISFET and p-type MISFET can be changed. Accordingly, the concentration profile of the impurity segregation layer formed at the interface of respective source/drain electrodes can individually optimized. Therefore, the interface resistance of the source/drain electrodes of each of the n-type MISFET and p-type MISFET can be optimized so that higher performance of a semiconductor device having the CMIS structure can be realized.

The semiconductor device in FIG. 1 manufactured by the manufacturing method in the present embodiment has, as described above, the As segregation layer in the n-type MISFET and the B segregation layer in the p-type MISFET of the source/drain. Further, the first silicide layer is thicker than the second silicide layer. With such a structure, the interface resistance having lower resistance can be realized. Further, based on a difference of mobility between electrons and holes, a reduction of parasitic resistance, which is required from the n-type MISFET more stringently than from the p-type MISFET, can be realized. By making the first silicide layer of the n-type MISFET twice or more as thick as the second silicide layer of the p-type MISFET at this time, it becomes possible to bring the channel resistance ratio and the resistance ratio of the NiSi layer of the bulk closer, further improving characteristics of a semiconductor device.

### Modification Of The First Embodiment

A semiconductor device and a manufacturing method of a semiconductor device in a modification of the first embodiment of the present invention are the same as a semiconductor device and a manufacturing method of a semiconductor device in the first embodiment except that each of the n-type MISFET and p-type MISFET has an extended diffusion layer and thus, a duplicate description thereof will be omitted.

FIG. 17 is a sectional view of a semiconductor device in the present modification. As shown in the figure, the n-type MISFET 200 has an extended diffusion layer 230 of As whose impurity concentration is, for example, 1×10²⁰ atoms/cm³. Also, the p-type MISFET 300 has the extended diffusion layer 230 of B whose impurity concentration is, for example, 1×10^{°} atoms/cm³.

A semiconductor device in the present modification can be manufactured, for example, by performing ion implantation of As in the first semiconductor region 250 where n-type MISFET is formed and ion implantation of B in the second semiconductor region 350 where p-type MISFET is formed after the gate electrodes 208 and 308 shown in FIG. 10 being formed by the manufacturing method of a semiconductor device in the first embodiment.

According to a semiconductor device and the manufacturing method of a semiconductor device in the present embodiment, by adding an extended diffusion layer, effects of optimization of MISFET characteristics, more concretely, the short channel effect and an effect of optimization with an operating current and the like being made easier are gained, in addition to effects of the first embodiment.

### SECOND EMBODIMENT

A manufacturing method of a semiconductor device in the second embodiment is the same as that of the first embodiment except that third heat treatment is added after performing ion implantation of B and Mg into the second silicide layer and thus, a duplicate description thereof will be omitted. According to the present embodiment, the interface resistance of p-type MISFET can further be reduced compared with the first embodiment.

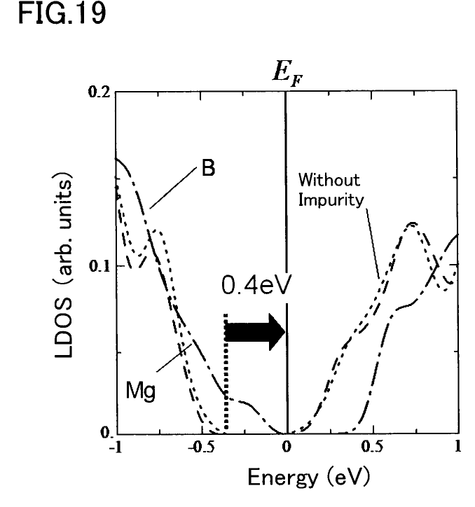

First, when Mg atoms are substituted for Si atoms in a NiSi layer/Si layer interface structure, how energy of the interface structure changes in accordance with the substitutional position of Mg atoms was calculated. A calculation result is shown in FIG. 18. A graph on the lower side is a result of plotting total energy of a corresponding crystal structure when each of Si atoms surrounded by a circle is replaced by one Mg atom in a crystal structure diagram on the upper side of FIG. 18. A crystal structure with lower energy is considered to be more stable. The reference (0 value) of energy is selected to be a case in which Mg atoms substitute for Si atoms in an Si layer bulk, that is, energy plotted at the right edge of the graph.

As is evident from FIG. 18, like B atoms, energy is lowest when Si atoms near the interface are replaced by Mg atoms and an energetically most stable site for Mg exists near the interface. Therefore, like B atoms, causing Mg atoms to segregate at the NiSi layer/Si layer interface can theoretically be considered to be possible.

FIG. 19 shows a result of calculation of the Schottky barrier height when an impurity segregation layer is formed from Mg atoms. The horizontal axis shows electron energy and the vertical axis shows a local density of states (LDOS). Also cases in which an impurity segregation layer is formed from B atoms and no impurity segregation layer is present are shown for comparison. As is evident from FIG. 19, an electric dipole has more influence at the interface when the impurity segregation layer is formed from Mg atoms than B atoms, lowering the Schottky barrier height. Therefore, forming an impurity segregation layer by adding Mg atoms to B atoms like the present embodiment is extremely effective in reducing the Schottky barrier height at the NiSi layer/Si layer interface of p-type MISFET and lowering the interface resistance.

Incidentally, an impurity segregation layer is formed from Mg atoms together with B atoms, instead of Mg atoms alone, in the present embodiment because the solubility limit of Mg atoms with respect to Si is lower than that of B atoms and thus, the Schottky barrier may not sufficiently fall due to a lack of impurity concentrations if an impurity segregation layer is formed from Mg atoms alone. However, the present invention does not exclude the possibility of forming an impurity segregation layer from Mg atoms alone.

Also a semiconductor device in the present embodiment can be manufactured by performing ion implantation of Mg atoms at the same time when ion implantation of B atoms into the second semiconductor region 350 is performed in a process shown in FIG. 15 according to the manufacturing method of a semiconductor device in the first embodiment.

### THIRD EMBODIMENT

A manufacturing method of a semiconductor device in the third embodiment is the same as that of the first embodiment except that the first metal and second metal also contain Pt instead of Ni alone and thus, a duplicate description thereof will be omitted. In the present embodiment, Ni containing Pt is deposited when the first metal 108 is deposited in FIG. 12 of the first embodiment. Also in FIG. 14 of the first embodiment, Ni containing Pt is deposited when the second metal 110 is deposited.

In the impurity post-implantation process, the annealing time becomes longer compared with an ordinary silicide process by a time needed for annealing to cause impurities to segregate after ion implantation. Therefore, anomalous diffusion of excessive Ni atoms in the NiSi layer into a channel part is more likely to occur. If such anomalous diffusion of Ni occurs, junction leakage increases, causing, for example, a problem of an increased leaking current of LSI.

Here, if a silicide is formed by causing a film formed by adding Pt to Ni to react with Si, anomalous diffusion of Ni is inhibited. Therefore, according to the manufacturing method of a semiconductor device in the present embodiment, in addition to effects of the first embodiment, an effect of being able to manufacture a semiconductor device in which junction leakage in the source/drain is inhibited is further gained.

Incidentally, the amount of Pt contained in an Ni film is preferably 5% or more and 10% or less in atomic percentage. This is because if the amount of Pt falls below this range, an effect of anomalous diffusion of Ni starts to diminish. If this range is exceeded, on the other hand, an increase in manufacturing costs due to the use of expensive Pt causes concern.

### FOURTH EMBODIMENT

A manufacturing method of a semiconductor device in the fourth embodiment is the same as that of the first embodiment except that ion implantation of As is performed instead of the first heat treatment, which is annealing treatment to form the first silicide layer, and thus, a duplicate description thereof will be omitted. The inventors found that a nickel silicide can be formed by performing ion implantation of As into a Ni film sputtered on silicon. A manufacturing method in the present embodiment applies this finding.

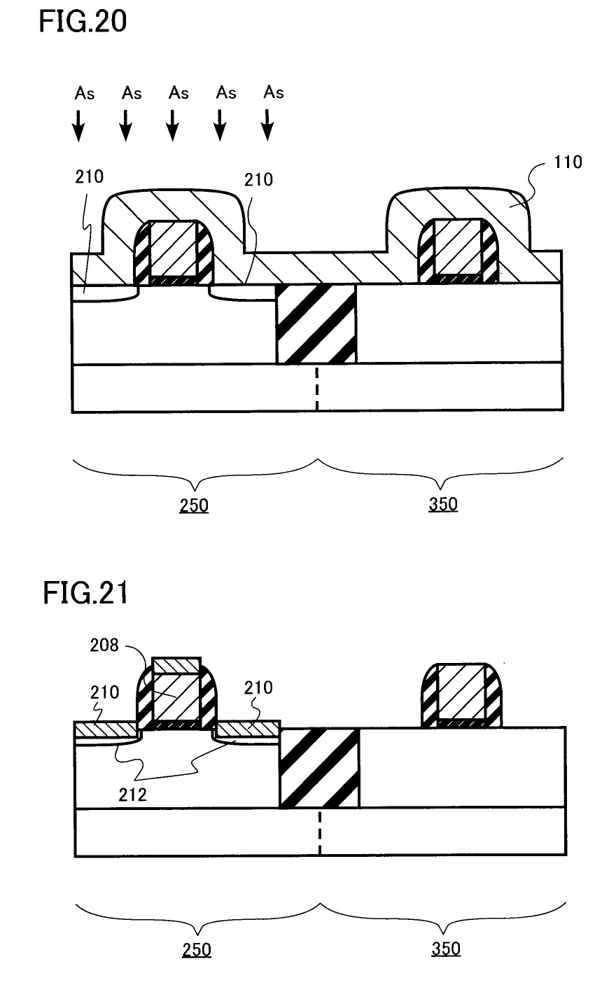

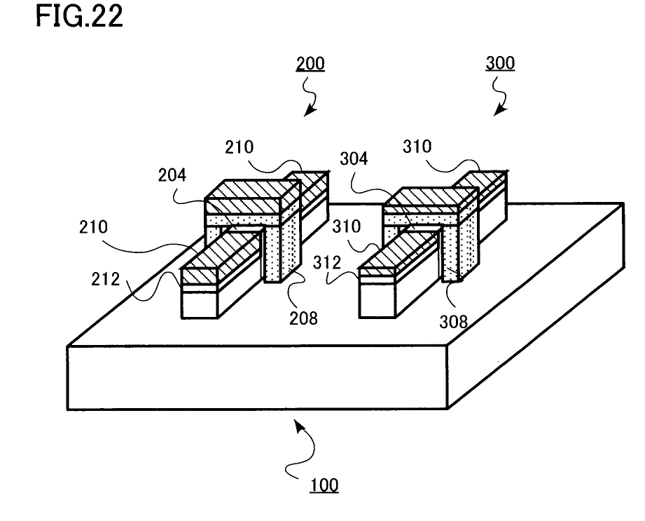

The manufacturing method of a semiconductor device in the present embodiment will be described more concretely with reference to FIG. 20 and FIG. 21. As shown in FIG. 11, the present embodiment is the same as the first embodiment until As (arsenic) is introduced into the first semiconductor region 250 by ion implantation using the gate electrode 208 and sidewall dielectric films 216 as a mask after masking the second semiconductor region 350 with a resist by lithography.

Next, as shown in FIG. 20, the Ni film 108 of the order of, for example, 10 nm in thickness is formed by, for example, the sputtering method on the first semiconductor region 250. That is, the Ni film 108 is deposited in such a way that the Ni film 108 is in contact with the source and drain regions of the n-type MISFET. Then, the second semiconductor region 350 is masked with a resist film and ion implantation of As onto the first semiconductor region 250 is performed.

Then, as shown in FIG. 21, the first semiconductor region 250 is silicided by heat generated by ion implantation of As to form the first silicide layer 210 made of NiSi of the order of 20 nm in thickness. At this time, the first gate silicide layer 214 is also formed on the gate electrode 208. Subsequently, the unreacted excessive Ni film 108 is separated by a chemical solution. Processes thereafter are the same as those of the first embodiment.

According to the present embodiment, the formation process of the protective film 106 to protect the second semiconductor region when forming a first silicide layer as shown in FIG. 12 is made unnecessary in comparison with the first embodiment. Therefore, in addition to effects of the first embodiment, it becomes possible to manufacture a high-performance semiconductor device having the CMIS structure by a still simpler process.

The silicidation process of an Ni film by ion implantation used in the present embodiment will be briefly described below. In order to calculate energy released when ion implantation of As atoms into an Si crystal is performed, energy generated when an As atom holds an interstitial position and further energy generated when an As atom holds an As substitutional position are calculated using the unit lattice Si₆₄. Generated energy can be calculated by using the following formula:

First, generated energy E_{f}^{Si} when an As atom holds an Si substitutional position in an Si layer is expressed as follows:
E_{f}^{Si}=−E (cell structure of 63 Si atoms including one As atom)

−E (one As atom in a bulk)

+E (cell structure of 64 Si atoms)

+E (one As atom in a vacuum)

Next, generated energy E_{f}^{int} when an As atom holds an interstitial position in an Si layer is expressed as follows:
E_{f}^{int}=−E (cell structure of 64 Si atoms including one As atom interstitially)

+E (cell structure of 64 Si atoms)
+E (one As atom in a vacuum)

However, the calculation was performed by assuming that when an As atom holds an Si substitutional position, an Si atom kicked out of a lattice point will return to an Si layer of a bulk again.

As a result, the following result was obtained:

E_{f}^{Si}=2.33 eV

E_{f}^{int}=−0.61 eV

Here, since generated energy is negative, As atoms basically cannot hold interstitial positions and will hold Si substitutional positions. Thus, energy of 2.33 eV will be released. That is, heat will be generated.

The surface concentration when, for example, the dose amount of 10¹⁶ atoms/cm² is implanted at 20 KeV is 10²¹ atoms/cm³. The temperature rise caused by ion implantation is determined by using heat capacity of a Si crystal per cm³ of 1.02×10¹⁹ eV/Kcm³. The result is (2.33 eV×10²¹)/(1.02×10¹⁹)=228 K.

Here, it is assumed that the temperature range in which an NiSi layer is formed is 350° C. to 500° C. Then, the dose amount of As required to realize this temperature is calculated to be from 2.4×10¹⁶ atoms/cm² to 3.0×10¹⁶ atoms/cm² because the temperature rise is proportional to the dose amount. Thus, in the manufacturing method of a semiconductor device in the present embodiment, the dose amount of ion implantation of As is preferably 2.4×10¹⁶ atoms/cm² or more and 3.0×10¹⁶ atoms/cm² or less.

### FIFTH EMBODIMENT

A manufacturing method of a semiconductor device in the fifth embodiment is the same as that of the first embodiment except that the n-type MISFET and p-type MISFET constituting the semiconductor device are Fin-type MISFETs and thus, a duplicate description thereof will be omitted. Here, a Fin-type MISFET is a MISFET having a channel region on a plate perpendicular to the semiconductor substrate and a gate electrode formed by sandwiching the channel region from both sides.

FIG. 22 is a perspective view of a semiconductor device in the present embodiment. As shown in FIG. 22, the semiconductor device in the present embodiment has, for example, the n-type MISFET 200 of the Fin type and the p-type MISFET 300 of the Fin type on the semiconductor substrate 100 of silicon. Then, the n-type MISFET 200 has on both sides of the first channel region 204 a source electrode and a drain electrode formed from the first silicide layer 210 made of, for example, NiSi and the As segregation layer 212 formed between the first channel region 204 and the first silicide layer 210.

The channel region 204 is in a Fin shape perpendicular to the semiconductor substrate 100 and has two principal surfaces opposite to each other. Then, a first gate dielectric film made of, for example, a silicon oxide is formed on each of the principal surfaces. The first gate electrode 208 is formed on the first gate dielectric film. The n-type MISFET in the present embodiment is, as described above, a Fin-type MISFET having a so-called double gate structure.

The p-type MISFET 300 has on both sides of the second channel region 304 a source electrode and a drain electrode formed from the second silicide layer 310 made of, for example, NiSi and the B segregation layer 312 formed between the second channel region 304 and the second silicide layer 310.

The channel region 304 is in a Fin shape perpendicular to the semiconductor substrate 100 and has two principal surfaces opposite to each other. Then, a second gate dielectric film made of, for example, a silicon oxide is formed on each of the principal surfaces. The second gate electrode 308 is formed on the second gate dielectric film. The p-type MISFET in the present embodiment is, as described above, a Fin-type MISFET having a so-called double gate structure.

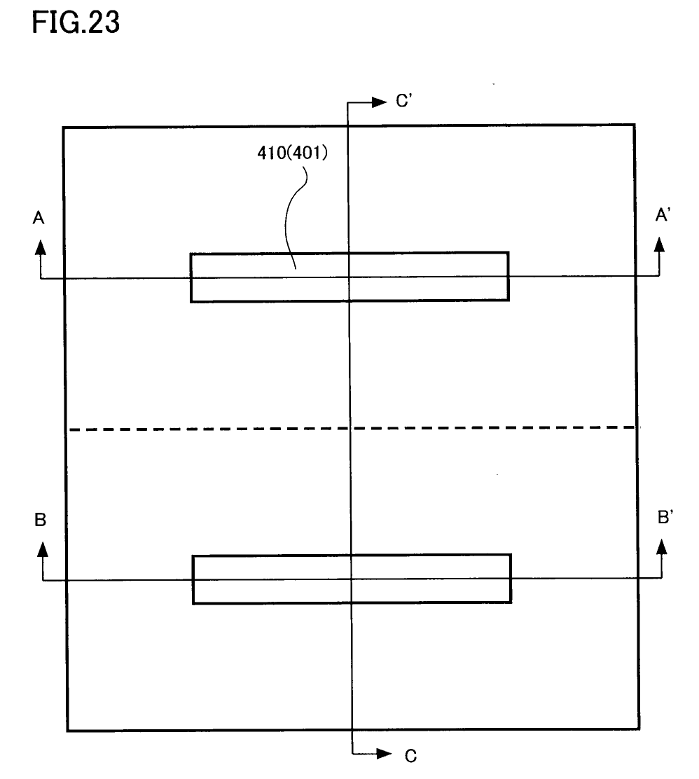

Next, the manufacturing method of a semiconductor device in the present embodiment will be described with reference to FIG. 23 to FIG. 49.

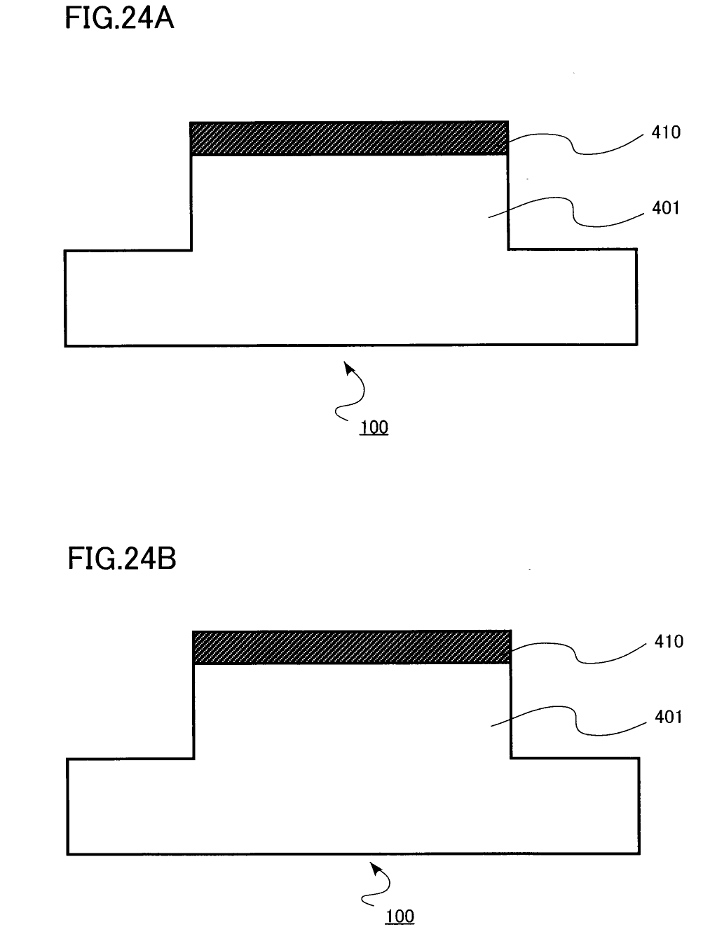

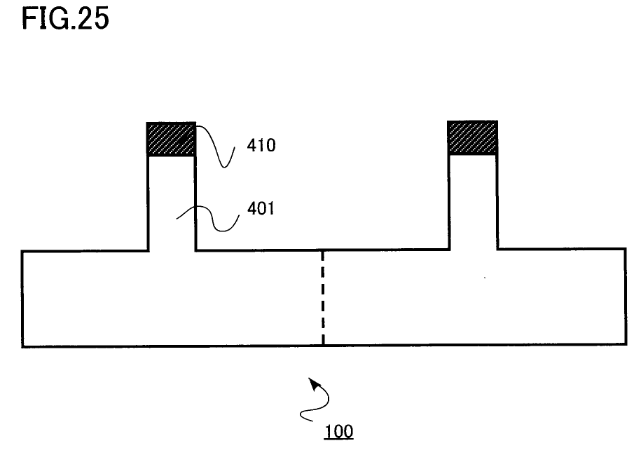

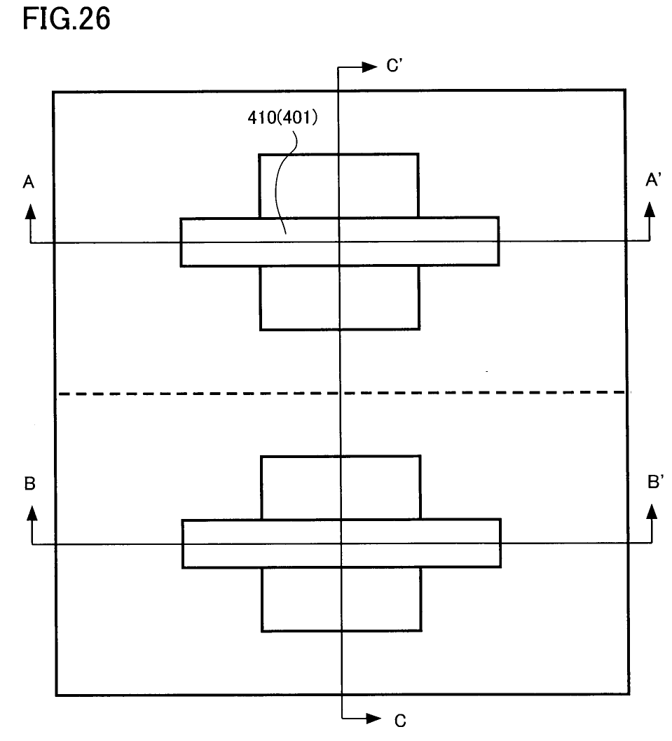

First, as shown in the plan view of FIG. 23, FIG. 24 (a) , which is a sectional view in the A-A′ direction of FIG. 23, FIG. 24 (b) , which is a sectional view in the B-B′ direction of FIG. 23, and FIG. 25, which is a sectional view in the C-C′ direction of FIG. 23, a dielectric film 410 to be a mask material such as a silicon nitride film of the order of 50 to 100 nm is deposited on the silicon semiconductor substrate 100. Then, the dielectric film 410 and the silicon substrate 100 are etched using etching technology such as lithography technology and reactive ion etching (hereinafter also referred to as RIE) to form an device region 401 and a groove to be an element isolation region.

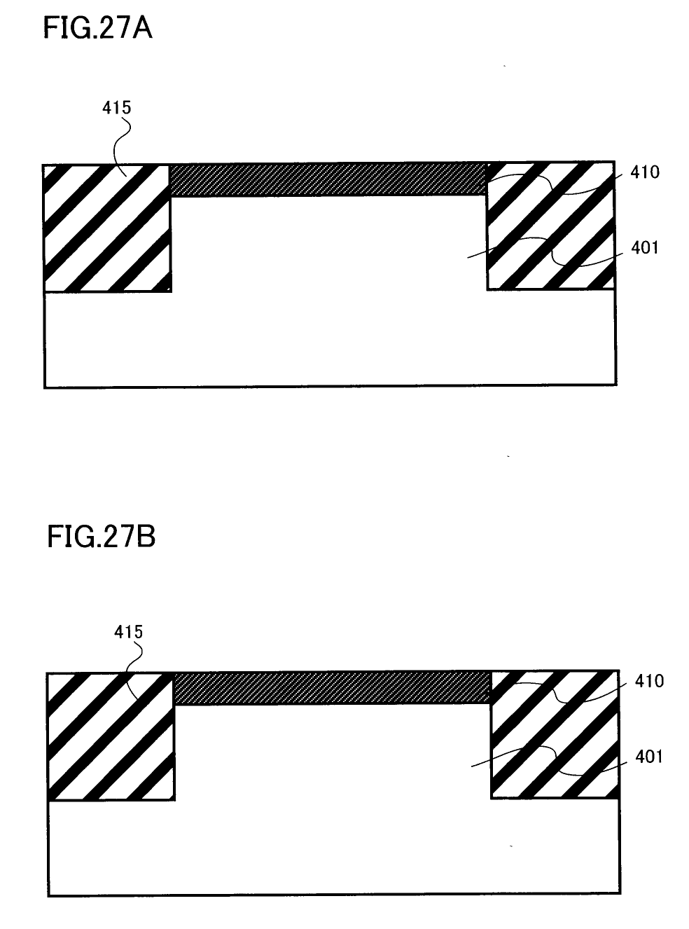

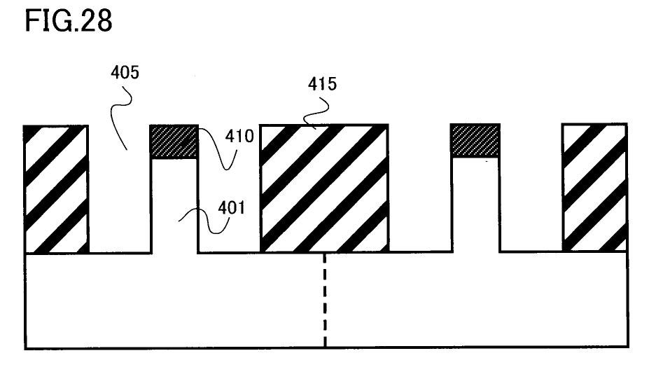

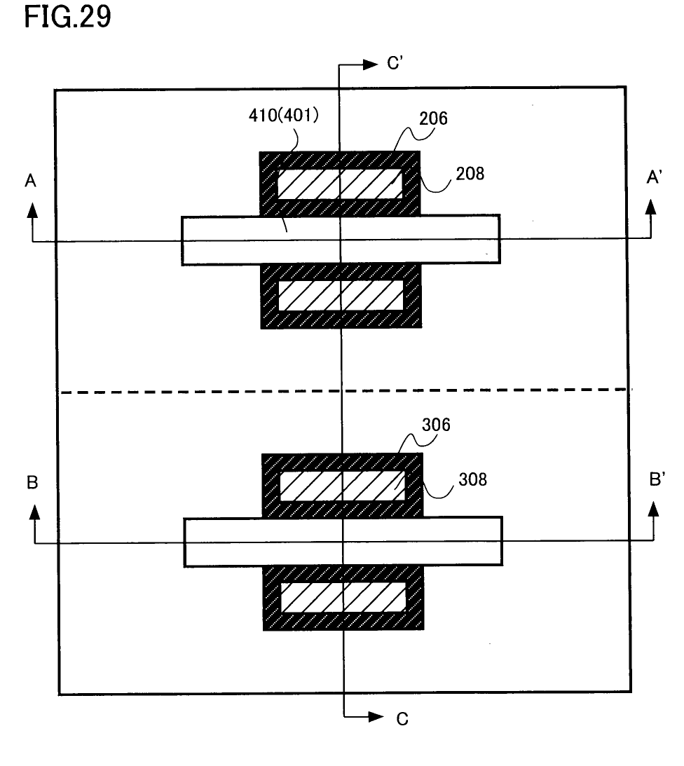

Next, as shown in the plan view of FIG. 26, FIG. 27 (a) , which is a sectional view in the A-A′ direction of FIG. 26, FIG. 27 (b) , which is a sectional view in the B-B′ direction of FIG. 26, and FIG. 28, which is a sectional view in the C-C′ direction of FIG. 26, a dielectric film 415 such as a silicon oxide is deposited in the groove to be the device isolation region and the dielectric film 415 is planarized up to the upper surface of the dielectric film 410 by the chemical-mechanical polishing (hereinafter also referred to as CMP) or the like to form the element isolation region. Then, a portion of the dielectric film 415 is removed and a groove 405 is formed in such a way that sidewalls of the device region 401 are exposed.

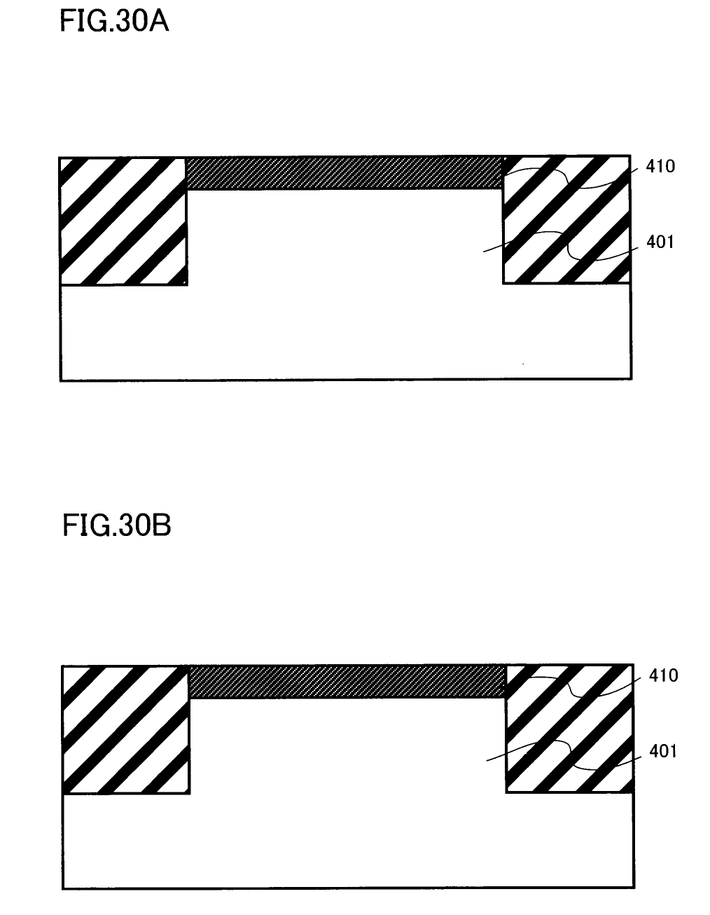

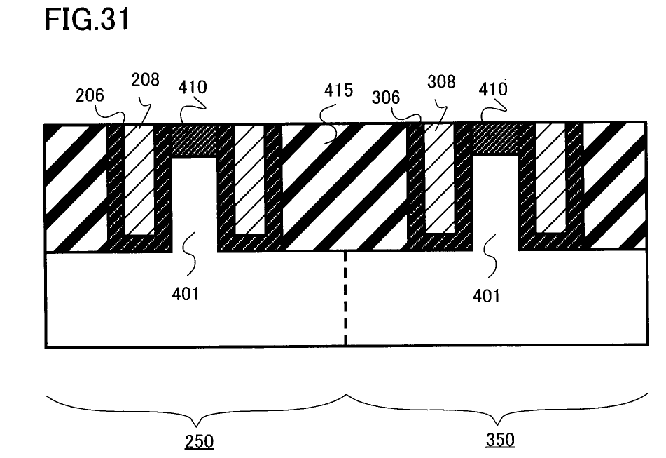

Next, as shown in the plan view of FIG. 29, FIG. 30(a) , which is a sectional view in the A-A′ direction of FIG. 29, FIG. 30(b), which is a sectional view in the B-B′ direction of FIG. 29, and FIG. 31, which is a sectional view in the C-C′ direction of FIG. 29, the first gate dielectric film 206 is formed on the sidewalls of the device region 401 of the first semiconductor region 250. Also, the second gate dielectric film 306 is formed on the sidewalls of the device region 401 of the second semiconductor region 350. These gate dielectric films 206 and 306 may be, for example, silicon oxides formed by thermal oxidization or a high-dielectric film formed by the CVD (Chemical Vapor Deposition) method or ALD (Atomic Layer Deposition) method.

Next, a conductive material to be the first gate electrode 208 and second gate electrode 308 is deposited on the first gate dielectric film 206 and second gate dielectric film 306 and the groove 405 is filled. Then, the conductive material filled until the upper surface of the dielectric film 410 is exposed and the gate dielectric films are planarized. Here, the conductive material to be the gate electrodes 208 and 308 is made of, for example, (doped) polysilicon, silicide, or metal.

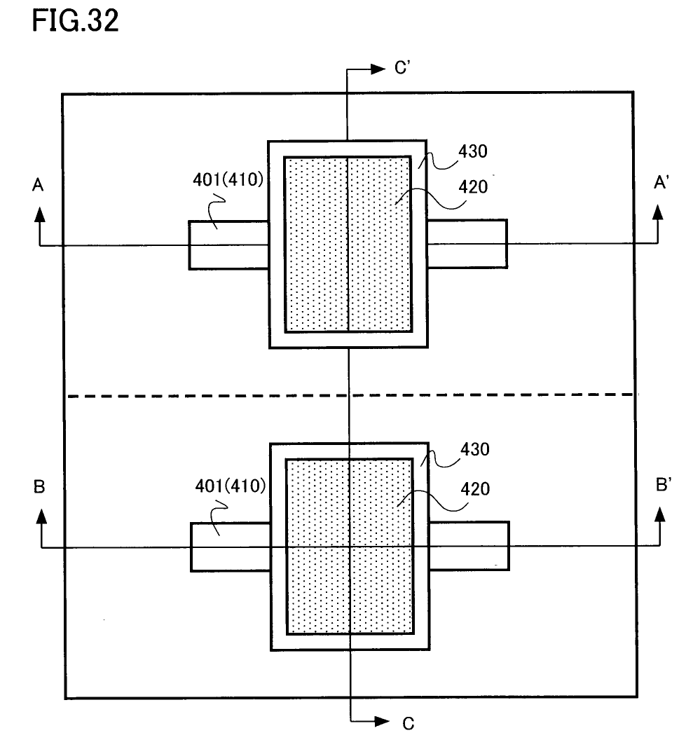

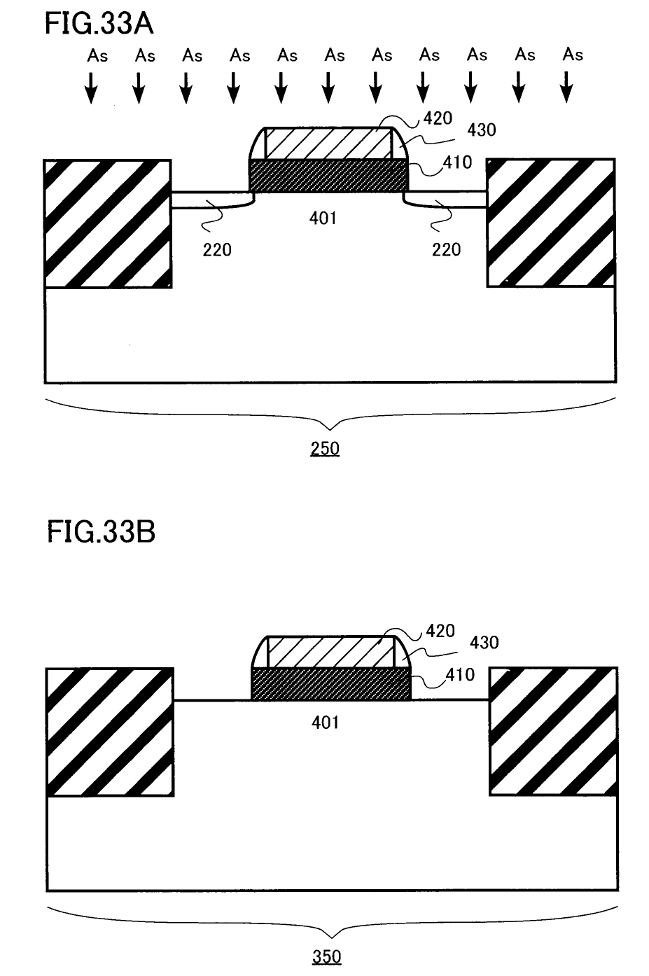

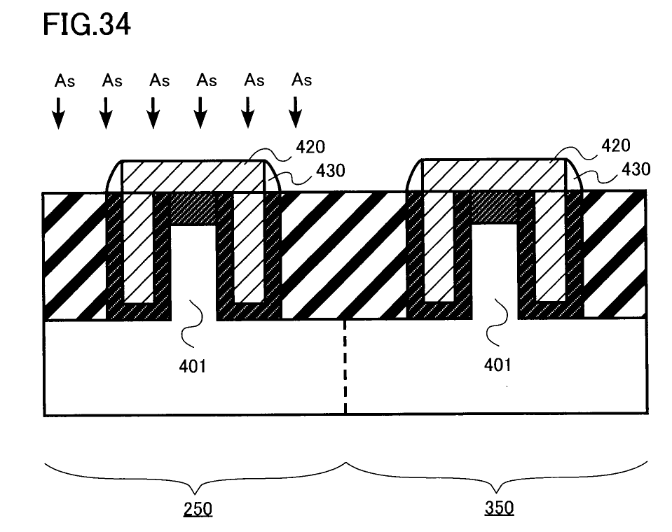

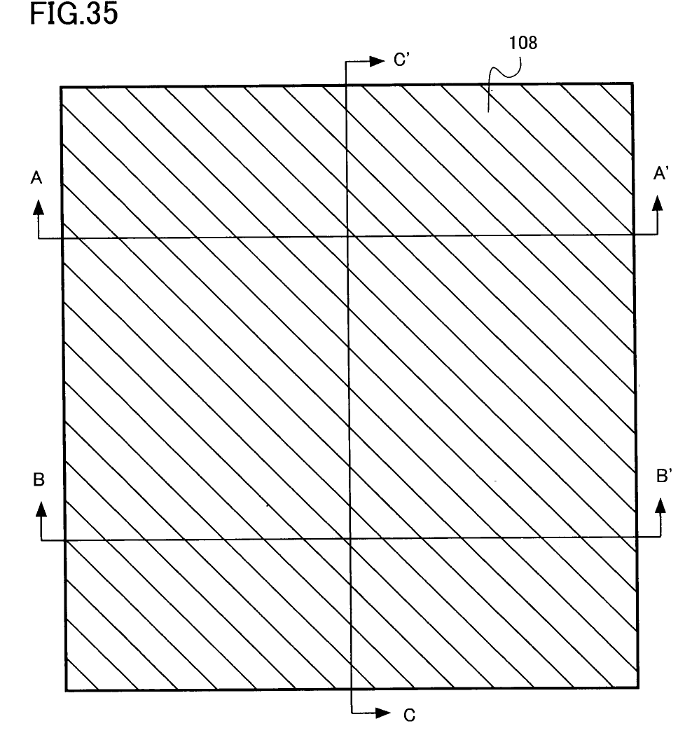

Next, as shown in the plan view of FIG. 32, FIG. 33 (a) , which is a sectional view in the A-A′ direction of FIG. 32, FIG. 33(b) , which is a sectional view in the B-B′ direction of FIG. 32, and FIG. 34, which is a sectional view in the C-C′ direction of FIG. 32, a conductive material to be a gate wire 420 is deposited. Then, the gate wire 420 is formed by lithography and RIE so that gate electrodes separated by the device region 401 is physically and electrically connected. Here, the gate wire 420 is made of, for example, (doped) polysilicon, silicide, or metal. Then, sidewall dielectric films 430 made of, for example, silicon nitride film, are formed on both sides of the gate wire 420.

Next, the second semiconductor region 350 is masked with a resist by lithography and the gate wire 420 and sidewall dielectric films 430 are used as a mask to introduce As (arsenic) into the first semiconductor region 250 by ion implantation. The n-type diffusion layer 220 of the order of, for example, 1×10²¹ atoms/cm³ is thereby formed.

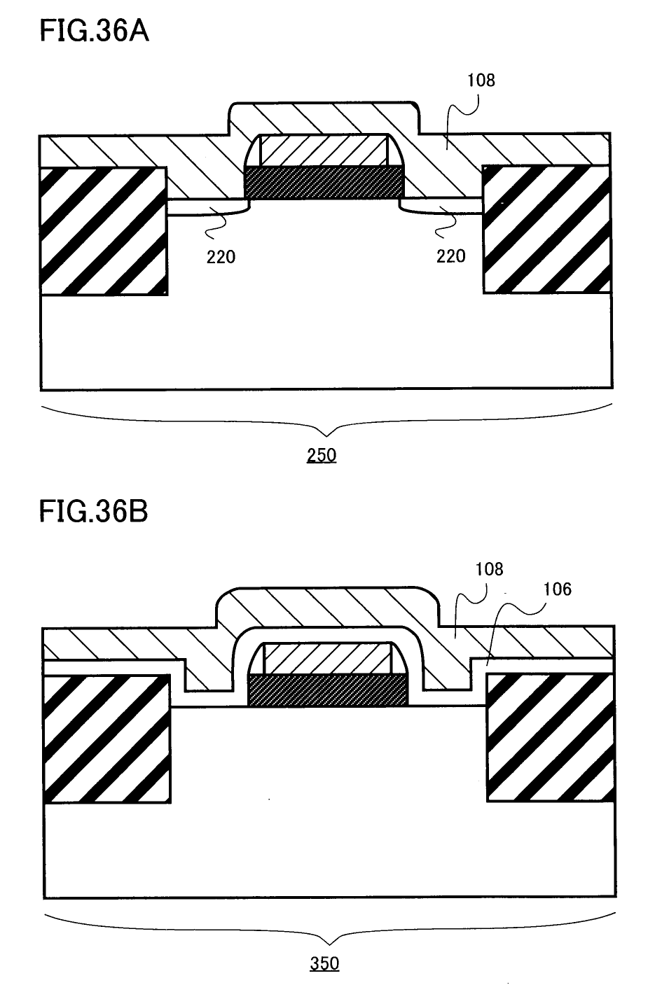

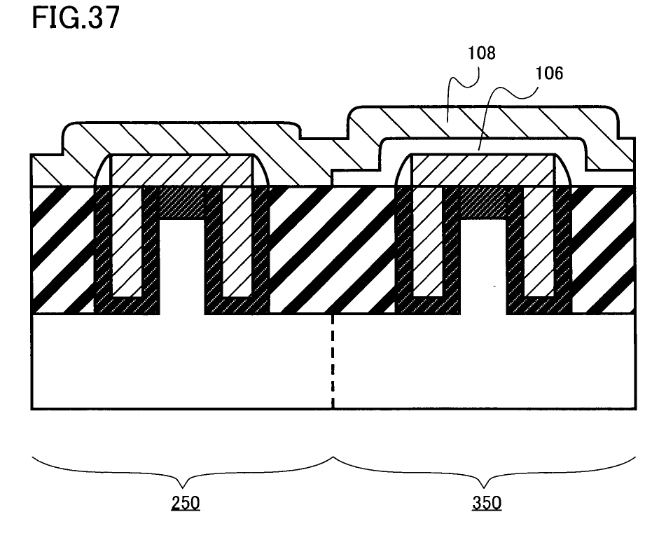

Next, as shown in the plan view of FIG. 35, FIG. 36(a), which is a sectional view in the A-A′ direction of FIG. 35, FIG. 36(b), which is a sectional view in the B-B′ direction of FIG. 35, and FIG. 37, which is a sectional view in the C-C′ direction of FIG. 35, the protective film 106 made of, for example, a silicon oxide is formed only on the second semiconductor region 350 by deposition using the LP-CVD method and patterning using lithography and RIE. Then, the Ni film 108 of the order of, for example, 10 nm in thickness is formed by, for example, the sputtering method on the first semiconductor region 250. That is, the Ni film 108 is deposited in such a way that the Ni film 108 is in contact with the source and drain regions of the n-type MISFET.

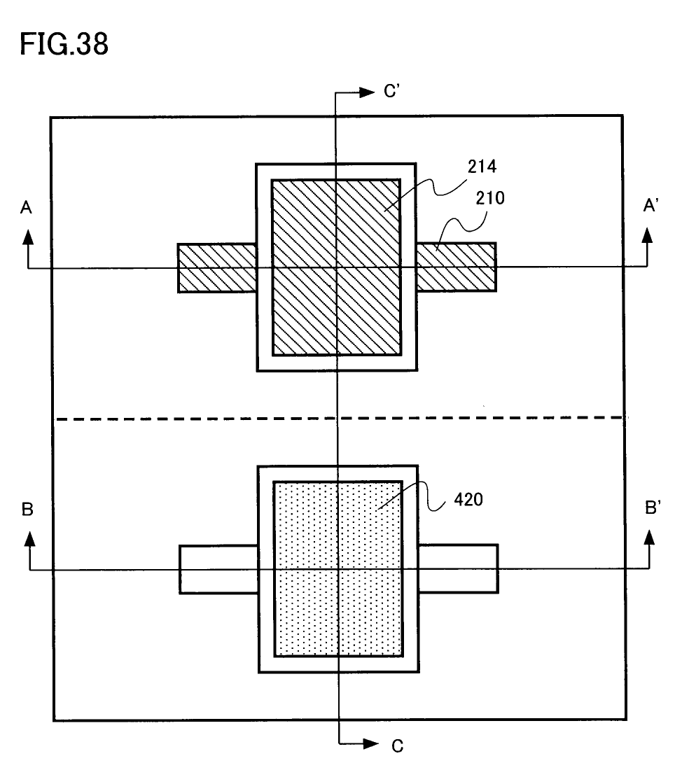

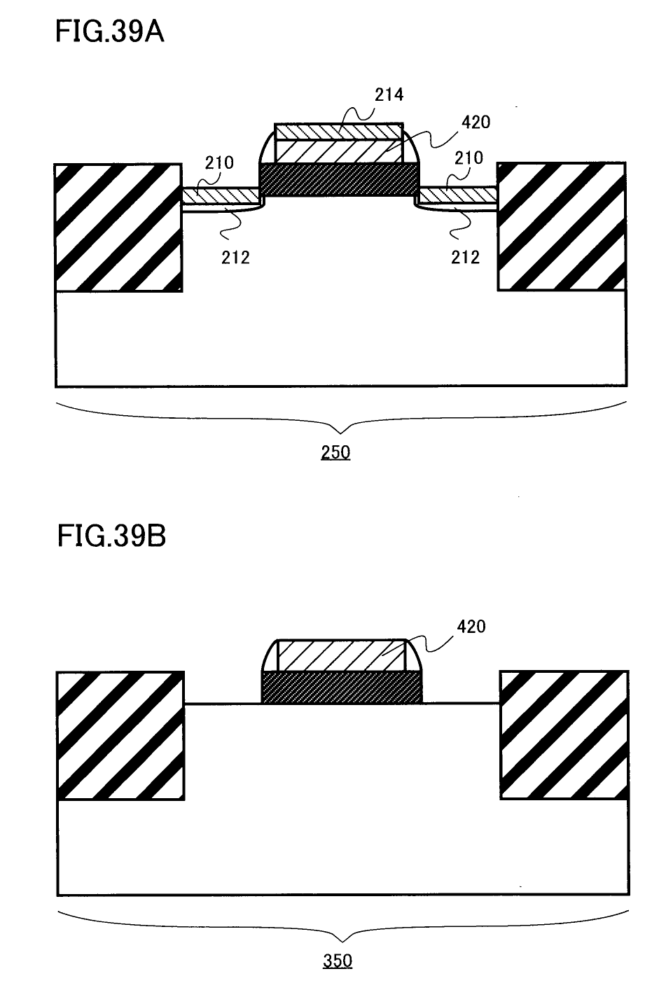

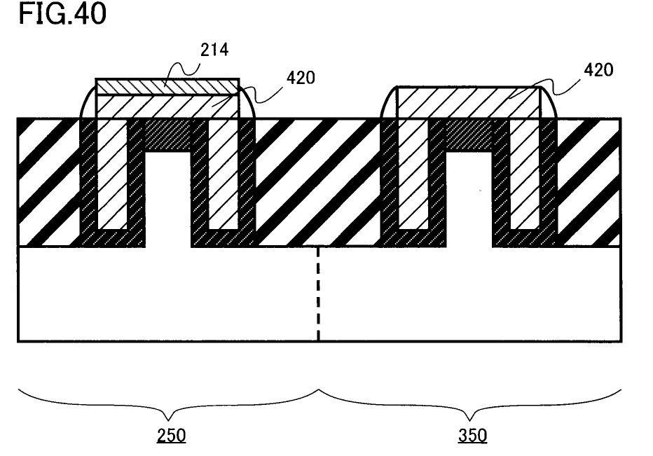

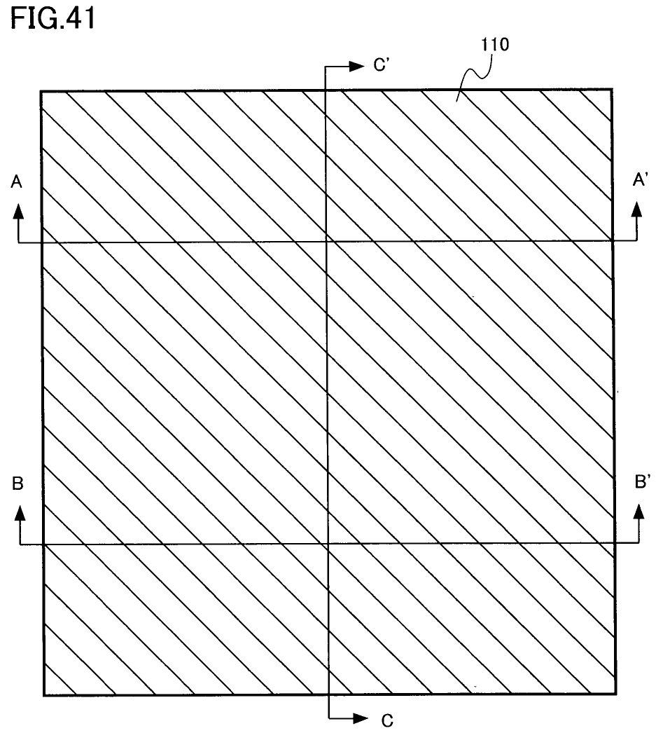

Next, as shown in the plan view of FIG. 38, FIG. 39(a), which is a sectional view in the A-A′ direction of FIG. 38, FIG. 39(b), which is a sectional view in the B-B′ direction of FIG. 38, and FIG. 40, which is a sectional view in the C-C′ direction of FIG. 38, annealing is performed at 350° C. for about 30 seconds by, for example, RTA as first heat treatment to form the first silicide layer 210 having the thickness of about 20 nm and made of NiSi through silicidation of the first semiconductor region 250. At this time, the first gate silicide layer 214 is also formed on the gate wire 420 in the first semiconductor region 250. Subsequently, the unreacted excessive Ni film 108 is separated by a chemical solution. With the n-type diffusion layer 220 being silicided when the first silicide layer 210 is formed, the As segregation layer 212 is formed as an interface, that is, an NiSi layer/Si layer interface of the first silicide layer 210.

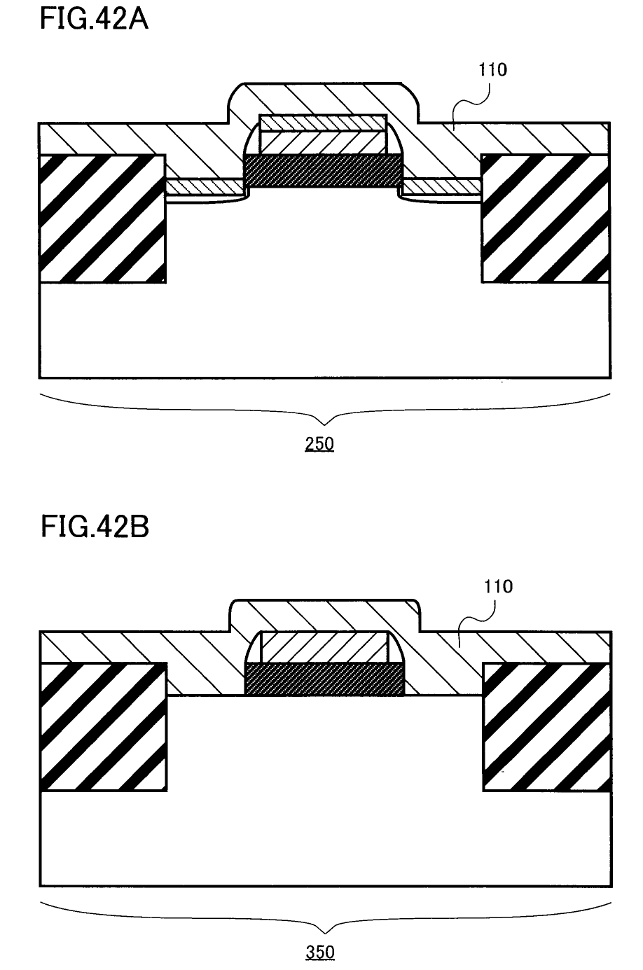

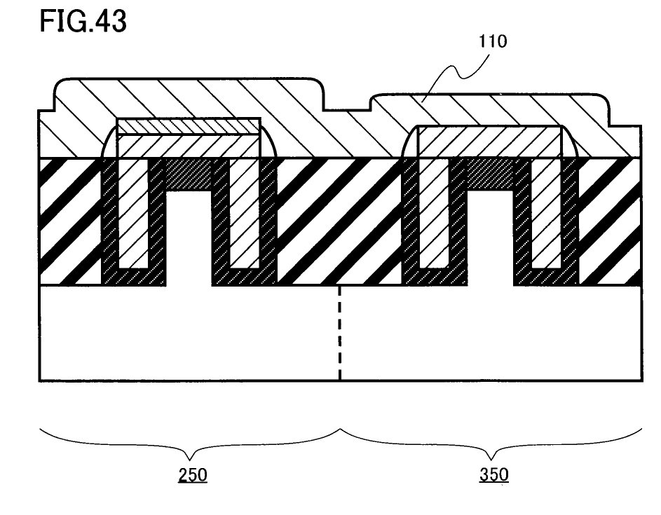

Next, as shown in the plan view of FIG. 41, FIG. 42(a), which is a sectional view in the A-A′ direction of FIG. 41, FIG. 42(b) , which is a sectional view in the B-B′ direction of FIG. 41, and FIG. 43, which is a sectional view in the C-C′ direction of FIG. 41, the Ni film 110 of the order of, for example, 8 nm in thickness is deposited by, for example, the sputtering method on the first semiconductor region 250 and the second semiconductor region 350.

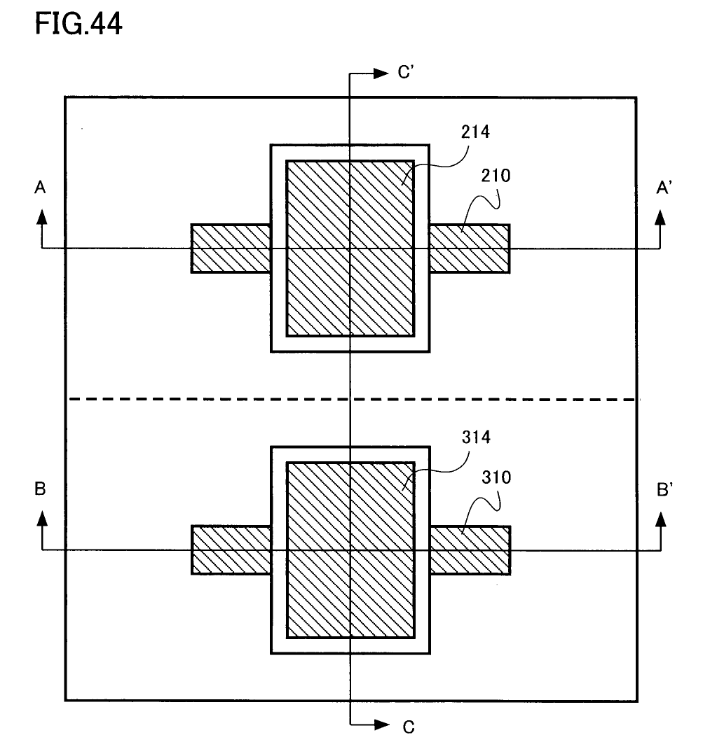

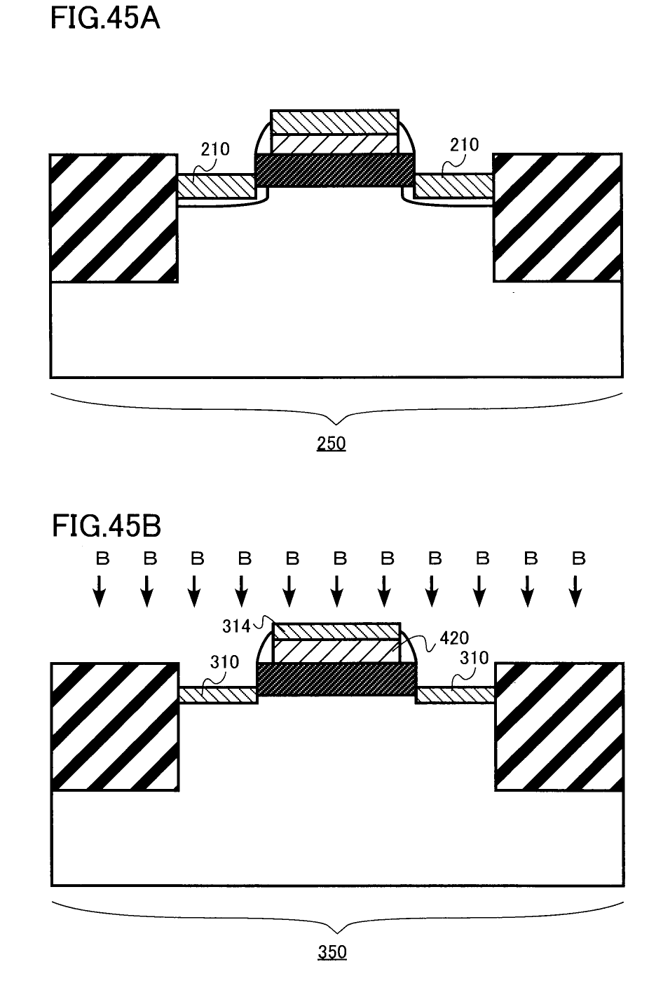

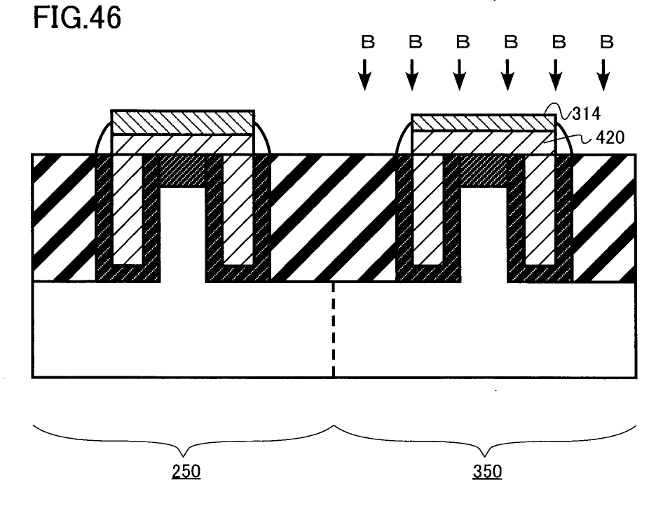

Next, as shown in the plan view of FIG. 44, FIG. 45(a), which is a sectional view in the A-A′ direction of FIG. 44, FIG. 45(b), which is a sectional view in the B-B′ direction of FIG. 44, and FIG. 46, which is a sectional view in the C-C′ direction of FIG. 44, annealing is performed at 500° C. for about 30 seconds by, for example, RTA as second heat treatment. Then, the first semiconductor region 250 formed earlier below the first silicide layer 210 is silicided to make the first silicide layer 210 thicker. The first silicide layer 210 will have the thickness of about 36 nm.

At the same time, the second semiconductor region 350 is silicided to form the second silicide layer 310 made of NiSi and of the order of 16 nm in thickness. At this time, the second gate silicide layer 314 is also formed on the gate wire 420 in the second semiconductor region 350. Subsequently, the unreacted excessive Ni film 110 is separated by a chemical solution.

Next, the first semiconductor region 250 is covered with a resist film (not shown) and then, ion implantation of B atoms onto the second semiconductor region 350 is performed. The B atoms will be introduced into the second silicide layer 310.

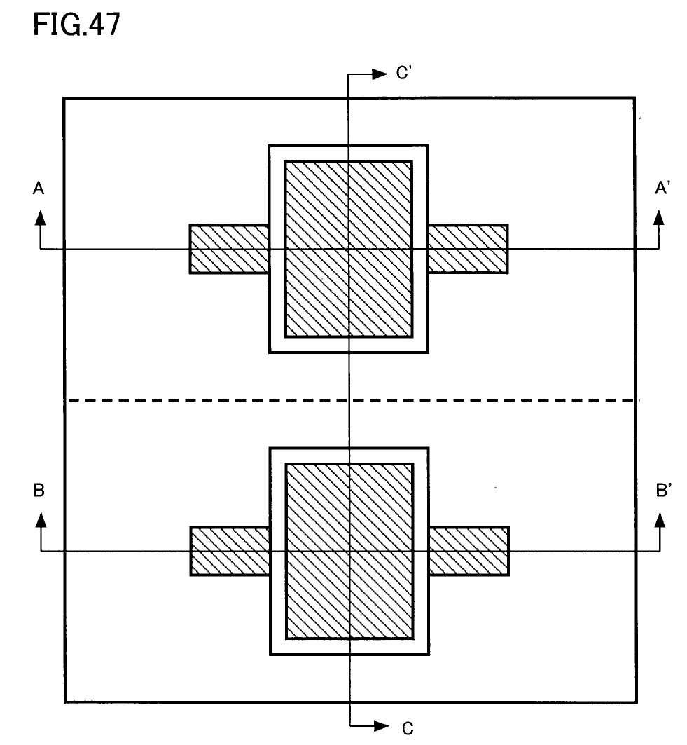

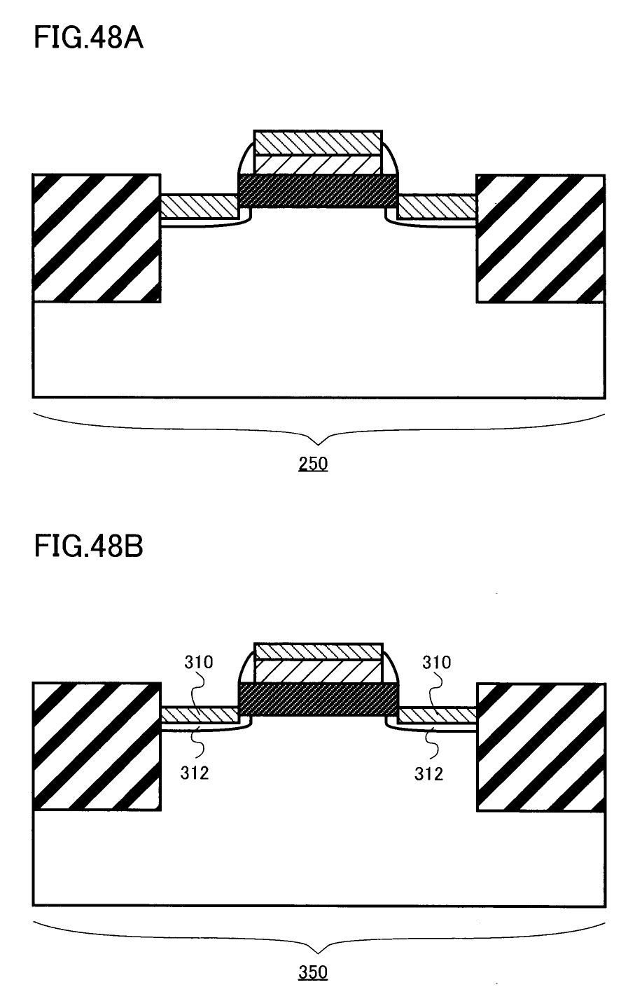

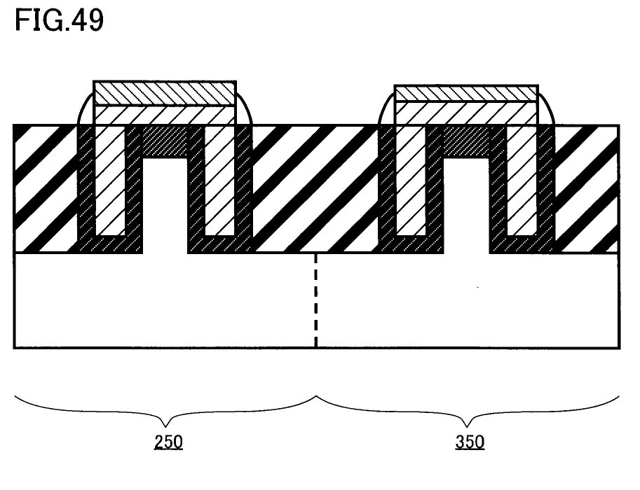

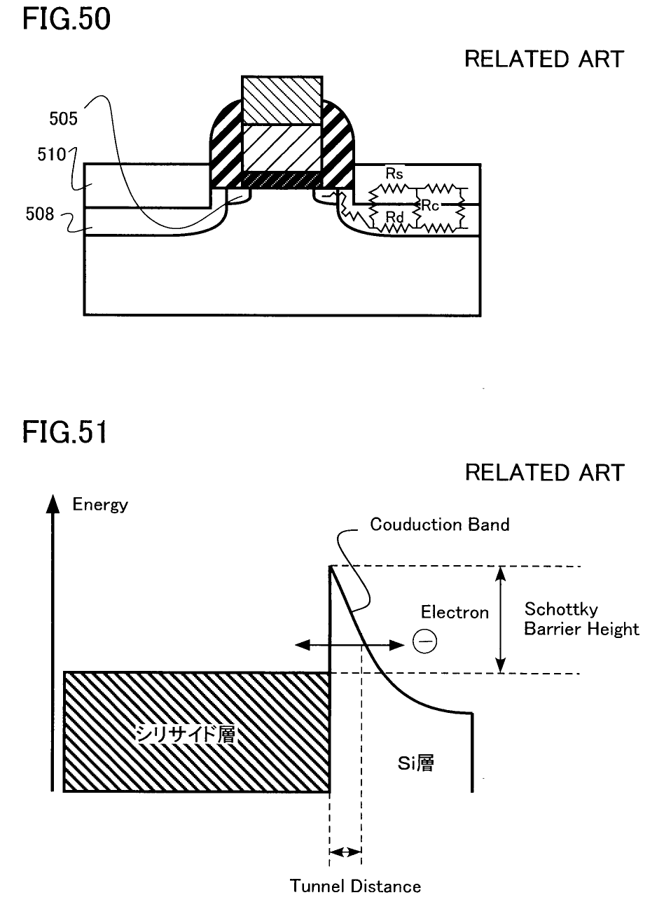

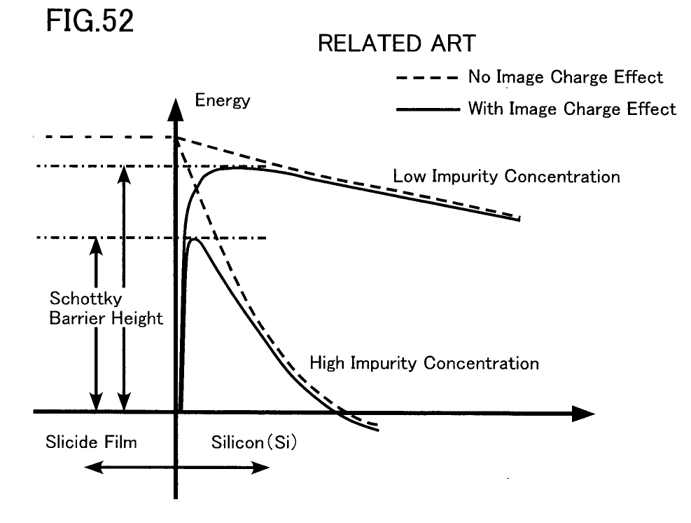

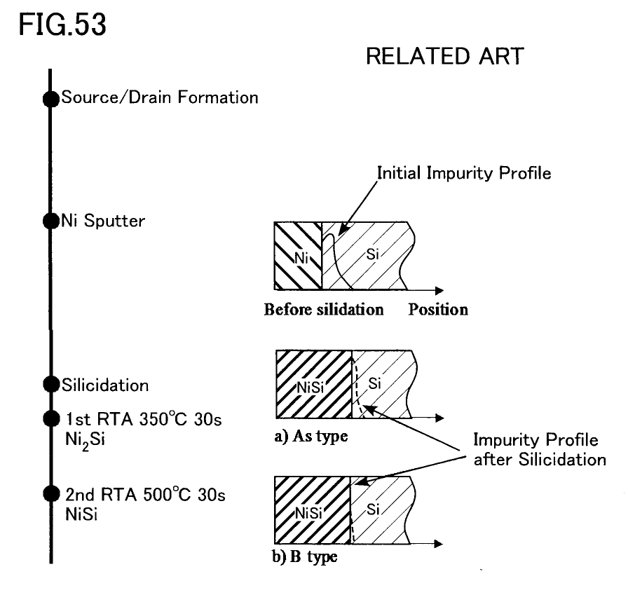

Next, as shown in the plan view of FIG. 47, FIG. 48 (a) , which is a sectional view in the A-A′ direction of FIG. 47, FIG. 48(b), which is a sectional view in the B-B′ direction of FIG. 47, and FIG. 49, which is a sectional view in the C-C′ direction of FIG. 47, annealing is performed at 500° C. for about 10 seconds by, for example, RTA as the third heat treatment. The B segregation layer 312 is formed by the annealing with B atoms being segregated at the interface of the second silicide layer 310, that is, at the NiSi layer/Si layer interface.

The semiconductor device in the present embodiment shown in FIG. 22 is manufactured in the manner described above. As has been described above, the first silicide layer 210 to be the source/drain electrodes of n-type MISFET and the second silicide layer 310 to be the source/drain electrodes of p-type MISFET are formed. Like a semiconductor device in the first embodiment, the first silicide layer 210 is made thicker than the second silicide layer 310.

Since controlling power of the gate is very strong in the Fin-type MISFET, drain induced barrier lowering can be inhibited and the Fin-type MISFET is resistant to the short channel effect. Thus, according to a semiconductor device and the manufacturing method thereof in the present invention, in addition to effects of the first embodiment, an effect of inhibiting the short channel effect can be gained.

Embodiments of the present invention have been described with reference to concrete examples. The above embodiments are shown only as examples and do not limit the present invention. Also when describing each embodiment, components that are not directly necessary for describing the present invention such as a semiconductor device and a manufacturing method of a semiconductor device have been omitted, but components involved in a semiconductor device or a manufacturing method of a semiconductor device can appropriately be selected and used. For example, embodiments have been described by assuming that the material of a semiconductor substrate is Si (silicon) , but the present invention can also be applied to semiconductor substrates made of other semiconductor materials, for example, a semiconductor substrate made of material SixGel-x (0≦x<1).

In addition, all semiconductor devices and all manufacturing methods of semiconductor devices that have elements of the present invention and can be appropriately designed/modified by a person skilled in the art are included in the scope of the present invention. The scope of the present invention is defined by the scope of claims and that of equivalents thereof.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents

What is claimed is:

1. A method of manufacturing a semiconductor device having an n-type MISFET and a p-type MISFET on a semiconductor substrate, comprising:
forming a gate dielectric film of the n-type MISFET on a first semiconductor region of the semiconductor substrate;
forming a gate dielectric film of the p-type MISFET on a second semiconductor region of the semiconductor substrate;
forming a gate electrode of the n-type MISFET on the gate dielectric film of the n-type MISFET;
forming a gate electrode of the p-type MISFET on the gate dielectric film of the p-type MISFET;
forming an n-type diffusion layer by ion implantation of As into the first semiconductor region;
depositing a first metal containing Ni onto the n-type diffusion layer;
forming a first silicide layer through silicidation of the n-type diffusion layer by first heat treatment;
depositing a second metal containing Ni onto the first sicilide layer and the second semiconductor region;
making the first silicide layer thicker through silicidation of the first semiconductor region and forming a second silicide layer through silicidation of the second semiconductor region by second heat treatment; and
providing third heat treatment after ion implantation of B or Mg into the second silicide layer.

2. The method according to claim 1, wherein thickness of the first silicide layer after the third heat treatment is double or more of that of the second silicide layer after the third heat treatment.

3. The method according to claim 1, wherein a depth of the first silicide layer after the third heat treatment is deeper than that of the n-type diffusion layer immediately before the first metal is deposited.

4. The method according to claim 1, wherein the first metal or the second metal contains Pt.

5. The method according to claim 1, wherein ion implantation of B and Mg into the second silicide layer is performed.

6. The method according to claim 1, wherein a temperature of the first heat treatment is lower than that of the second heat treatment.

7. The method according to claim 1, wherein a temperature of the third heat treatment is 350° C. or higher and 550 ° C. or lower.

8. The method according to claim 1, wherein the n-type MISFET and the p-type MISFET are Fin-type MISFETs.

9. A method of manufacturing a semiconductor device having an n-type MISFET and a p-type MISFET on a semiconductor substrate, comprising:
forming a gate dielectric film of the n-type MISFET on a first semiconductor region of the semiconductor substrate;
forming a gate dielectric film of the p-type MISFET on a second semiconductor region of the semiconductor substrate;
forming a gate electrode of the n-type MISFET on the gate dielectric film of the n-type MISFET;
forming a gate electrode of the p-type MISFET on the gate dielectric film of the p-type MISFET;
forming an n-type diffusion layer by ion implantation of As into the first semiconductor region;
depositing a first metal containing Ni onto the n-type diffusion layer;
forming a first silicide layer through silicidation of the n-type diffusion layer by ion implantation of As into the first metal;
depositing a second metal containing Ni onto the first sicilide layer and the second semiconductor region;
making the first silicide layer thicker through silicidation of the n-type diffusion layer and forming a second silicide layer through silicidation of the second semiconductor region by first heat treatment; and
providing second heat treatment after ion implantation of B or Mg into the second silicide layer.

10. The method according to claim 9, wherein a dose amount of As when ion implantation of As into the first metal is performed is 2.4×10¹⁶ atoms/cm² or more and 3.0×10¹⁶ atoms/cm² or less.

11. The method according to claim 9, wherein thickness of the first silicide layer after the second heat treatment is double or more of that of the second silicide layer after the second heat treatment.

12. The method according to claim 9, wherein a depth of the first silicide layer after the second heat treatment is deeper than that of the n-type diffusion layer immediately before the first metal is deposited.

13. The method according to claim 9, wherein the first metal or the second metal contains Pt.

14. The method according to claim 9, wherein ion implantation of B and Mg into the second silicide layer is performed.

15. The method according to claim 9, wherein a temperature of the second heat treatment is 350° C. or higher and 550° C. or lower.

16. The method according to claim 9, wherein the n-type MISFET and the p-type MISFET are Fin-type MISFETs.

17. A semiconductor device having an n-type MISFET and a p-type MISFET on a semiconductor substrate, wherein the n-type MISFET comprising:
a first channel region in the semiconductor substrate;
a first gate dielectric film formed on the first channel region;
a first gate electrode formed on the first gate dielectric film;
a source electrode and a drain electrode formed of a first silicide layer containing Ni on both sides of the first channel region; and
an As segregation layer formed between the first channel region and the first silicide layer, and the p-type MISFET comprising:
a second channel region in the semiconductor substrate;
a second gate dielectric film formed on the second channel region;
a second gate electrode formed on the second gate dielectric film;
a source electrode and a drain electrode formed of a second silicide layer containing Ni on both sides of the second channel region; and
a segregation layer containing B or Mg formed between the second channel region and the second silicide layer, wherein the first silicide layer is thicker than the second silicide layer.

18. The device according to claim 17, wherein thickness of the first silicide layer is double or more of that of the second silicide layer.

19. The device according to claim 17, wherein the n-type MISFET and the p-type MISFET are Fin-type MISFETs.

20. The device according to claim 17, wherein the segregation layer contains both B and Mg.
